(19) United States
(12) Patent Application Publication
(10) Pub. No.: US 2025/0107315 A1
(43) Pub. Date: Mar. 27, 2025

(54) DISPLAY DEVICE AND MANUFACTURING METHOD THEREFOR

(71) Applicant: Sharp Display Technology Corporation, Kameyama City, Mie (JP)

(72) Inventors: Yusuke SAKAKIBARA, Kameyama City, Mie (JP); Yoshihiro UETA, Kameyama City, Mie (JP)

(21) Appl. No.: 18/728,096

(22) PCT Filed: Feb. 17, 2022
(86) PCT No.: PCT/JP2022/006360

§ 371 Date: Jul. 11, 2024

(51) Int. Cl. H10K 50/115; H10K 59/35

(52) U.S. Cl. CPC H10K 50/115; H10K 59/35

(57) ABSTRACT

In a display device, a light-emitting layer of at least one subpixel includes a first region, and a second region having a number of inorganic ligands contained per unit volume less than a number of the inorganic ligands contained per unit volume in the first region. The first region includes a central portion of the light-emitting layer, and the second region includes at least one end portion among end portions, of the light-emitting layer, adjacent to other adjacent subpixels.

### TECHNICAL FIELD

The disclosure relates to a display device and a manufacturing method for the display device.

### BACKGROUND ART

On the surface of a quantum dot, a ligand is generally provided for the purpose of protecting the quantum dot and improving dispersibility of the quantum dot in a solvent. As the ligand, an organic ligand is generally used. Conversely, in recent years, an inorganic ligand has attracted attention as a ligand replacing the organic ligand.

The inorganic ligand has higher stability than the organic ligand, and is excellent in current injection properties. For example, PTL 1 discloses a stable nanostructure composition including a nanostructure and, as the inorganic ligand, a specific fluoride-containing ligand or fluoride anion. PTL 1 exemplifies a quantum dot as one type of nanostructure.

### CITATION LIST

### Patent Literature

PTL 1: JP 2020-180278 A

### SUMMARY

### Technical Problem

However, a quantum dot containing an inorganic ligand, such as a halogen ligand containing a fluoride, emits light even with a slight leakage current. Thus, in a display device including a light-emitting layer formed of such a quantum dot, when one subpixel emits light, a leakage current from the subpixel causes a subpixel adjacent to the subpixel to emit light. As a result, optical crosstalk such as color mixing or formation of an unclear image occurs. Such crosstalk causes deterioration in display quality of the display device.

An aspect of the disclosure has been made in view of the above-described problems, and an object thereof is to provide a display device and a manufacturing method for the display device capable of achieving both improvement in light emission efficiency, stability, and current injection properties by an inorganic ligand, and suppression of light emission due to a leakage current from an adjacent subpixel.

### Solution to Problem

In order to solve the problem described above, according to an aspect of the disclosure, a display device includes a plurality of subpixels. Each of the plurality of subpixels includes a first electrode, a second electrode, and a function layer provided between the first electrode and second electrode and including at least a light-emitting layer. The light-emitting layer of at least one subpixel of the plurality of subpixels includes a first region including a quantum dot and including, of an organic ligand and an inorganic ligand, at least the inorganic ligand, and a second region including the quantum dot and including, of the organic ligand and the inorganic ligand, at least the organic ligand, a number of a plurality of the inorganic ligands included per unit volume in the second region being less than a number of the plurality of inorganic ligands included per unit volume in the first region. The first region includes a central portion of the light-emitting layer of the at least one subpixel, and the second region includes at least one end portion among end portions, of the light-emitting layer of the at least one subpixel, adjacent to other subpixels of the plurality of subpixels respectively adjacent to the at least one subpixel.

In order to solve the problem described above, according to an aspect of the disclosure, a manufacturing method for a display device is a manufacturing method for a display device including a plurality of subpixels, each of the plurality of subpixels including a first electrode, a second electrode, and a function layer provided between the first electrode and second electrode and including at least a light-emitting layer. The manufacturing method for the display device includes forming the first electrode, forming the function layer, and forming the second electrode. The forming the function layer includes forming the light-emitting layer. In the forming the light-emitting layer, as the light-emitting layer of at least one subpixel of the plurality of subpixels, the light-emitting layer is formed that includes a first region including a quantum dot and including, of an organic ligand and an inorganic ligand, at least the inorganic ligand, and a second region including the quantum dot and including, of the organic ligand and the inorganic ligand, at least the organic ligand, a number of a plurality of the inorganic ligands contained per unit volume being less than a number of the plurality of inorganic ligands contained per unit volume in the first region. The first region includes a central portion of the light-emitting layer of the at least one subpixel, and the second region includes at least one end portion among end portions, of the light-emitting layer of the at least one subpixel, adjacent to other subpixels adjacent to the at least one subpixel.

### Advantageous Effects of Disclosure

According to an aspect of the disclosure, a display device and a manufacturing method for the display device are provided that can achieve both improvement in light emission efficiency by an inorganic ligand and suppression of light emission due to a leakage current from an adjacent subpixel.

### BRIEF DESCRIPTION OF DRAWINGS

FIG. 1 is a plan view illustrating an example of a schematic configuration of main portions of a display device according to a first embodiment.

FIG. 2 is a plan view illustrating an example of a schematic configuration of a subpixel in a pixel region of the display device according to the first embodiment.

FIG. 3 is a cross-sectional view illustrating an example of a schematic configuration of the main portions of the display device according to the first embodiment.

FIG. 4 is an enlarged cross-sectional view schematically illustrating a part of a light-emitting layer of each color according to an example of the display device according to the first embodiment.

FIG. 5 is a cross-sectional view for explaining a leakage current between a first subpixel and a second subpixel of a display device for comparison.

FIG. 6 is a circuit diagram for explaining the leakage current between the first subpixel and the second subpixel of the display device for comparison illustrated in FIG. 5.

FIG. 7 is a flowchart of an example of a manufacturing method for the display device according to the first embodiment.

FIG. 8 is a flowchart illustrating an example of a function layer forming step illustrated in FIG. 7.

FIG. 9 is a flowchart illustrating an example of a light-emitting layer forming step illustrated in FIG. 8.

FIG. 10 is a cross-sectional view illustrating an example of a part of a first light-emitting layer forming step illustrated in FIG. 9.

FIG. 11 is a partially enlarged cross-sectional view schematically illustrating steps subsequent to steps illustrated in FIG. 10 in the first light-emitting layer forming step illustrated in FIG. 9.

FIG. 12 is a cross-sectional view illustrating an example of a part of a second light-emitting layer forming step illustrated in FIG. 9.

FIG. 13 is a partially enlarged cross-sectional view schematically illustrating steps subsequent to steps illustrated in FIG. 12 in the second light-emitting layer forming step illustrated in FIG. 9.

FIG. 14 is a schematic cross-sectional view illustrating an example of a third light-emitting layer forming step illustrated in FIG. 9.

FIG. 15 is a partially enlarged cross-sectional view schematically illustrating steps subsequent to steps illustrated in FIG. 14 in the third light-emitting layer forming step illustrated in FIG. 9.

FIG. 16 is a cross-sectional view illustrating another example of a part of the third light-emitting layer forming step according to a modified example of the first embodiment.

FIG. 17 is a cross-sectional view illustrating a part of the light-emitting layer forming step according to a second embodiment.

FIG. 18 is a cross-sectional view illustrating steps subsequent to steps illustrated in FIG. 17 in the light-emitting layer forming step according to the second embodiment.

FIG. 19 is a partially enlarged cross-sectional view schematically illustrating steps subsequent to steps illustrated in FIG. 18 at the light-emitting layer forming step according to the second embodiment.

FIG. 20 is a partially enlarged cross-sectional view schematically illustrating a part of the light-emitting layer forming step according to a second modified example of the second embodiment.

FIG. 21 is a partially enlarged cross-sectional view schematically illustrating a part of the light-emitting layer forming step according to a third modified example of the second embodiment.

FIG. 22 is a flowchart illustrating an example of the light-emitting layer forming step according to a fourth modified example of the second embodiment.

FIG. 23 is a plan view illustrating an example of a schematic configuration of the subpixel in the display device according to a third embodiment.

FIG. 24 is a plan view illustrating an example of a schematic configuration of the subpixel in the display device according to a fourth embodiment.

FIG. 25 is a plan view illustrating an example of a schematic configuration of the subpixel in the display device according to a fifth embodiment.

FIG. 26 is a plan view illustrating an example of a schematic configuration of the subpixel in the display device according to a sixth embodiment.

FIG. 27 is a graph showing a relationship, in a reference subpixel, between a distance from a subpixel end, a voltage increase amount of the reference subpixel due to driving of a subpixel adjacent to the reference subpixel, and a light emission threshold voltage increase amount of the reference subpixel.

FIG. 28 is a cross-sectional view illustrating an example of a schematic configuration of main portions of the display device according to a seventh embodiment.

FIG. 29 is a cross-sectional view illustrating a part of the light-emitting layer forming step according to an eighth embodiment.

FIG. 30 is a cross-sectional view illustrating another example of the light-emitting layer forming step according to the eighth embodiment.

### DESCRIPTION OF EMBODIMENTS

Hereinafter, embodiments of the disclosure will be described in detail. Note that, in each of the embodiment described below, members having the same functions as those of members described earlier will be denoted by the same reference numerals and signs, and the description thereof will not be repeated. In the second embodiment and those following, differences from the embodiment described first will be described. Note that it should be obvious that even in a case where not specified, in the second embodiment and those following, the same modifications as those of the embodiment described first may also be applied. Further, hereinafter, a description of “from A to B” for two numbers A and B is intended to mean “equal to or greater than A and equal to or less than B”, unless otherwise specified.

### First Embodiment

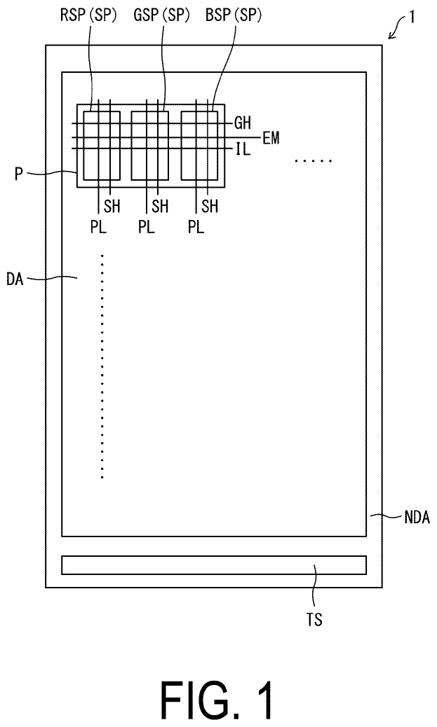

FIG. 1 is a plan view illustrating an example of a schematic configuration of main portions of a display device 1 according to the present embodiment.

As illustrated in FIG. 1, the display device 1 includes a pixel region DA including a plurality of pixels P each including a plurality of subpixels SP, and a frame region NDA provided around the pixel region DA so as to surround the pixel region DA.

In the frame region NDA, a terminal portion TS into which is input a signal for driving each of the subpixels SP is provided. Note that the terminal portion TS may be provided with an electronic circuit board (not illustrated) such as an integrated circuit (IC) chip and a flexible printed circuit (FPC) board, for example.

In the pixel region DA, for example, a plurality of wiring lines including a plurality of gate wiring lines GH, a plurality of light emission control lines EM, and a plurality of initialization potential lines IL are provided to extend in a row direction. Further, in the pixel region DA, for example, a plurality of wiring lines including a plurality of power source lines PL and a plurality of source wiring lines SH are provided to extend in a column direction. The plurality of subpixels SP are provided in a matrix shape, for example, respectively corresponding to intersecting portions of the gate wiring lines GH and the source wiring lines SH.

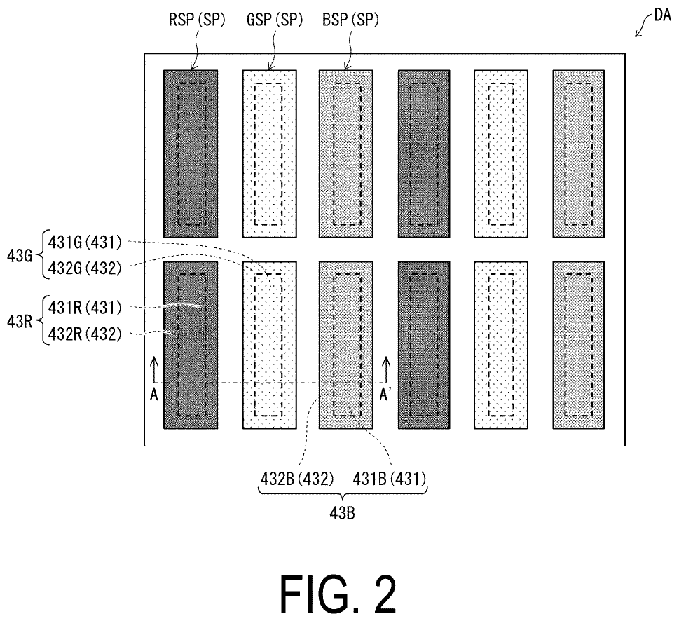

FIG. 2 is a plan view illustrating an example of a schematic configuration of the subpixel SP in the pixel region DA of the display device 1 illustrated in FIG. 1. Note that in FIG. 2, the number of the subpixels SP is reduced for convenience of illustration.

As illustrated in FIGS. 1 and 2, the display device 1 includes, as the subpixels SP, the subpixels SP having different luminescent colors. Specifically, the display device 1 includes, as the subpixels SP, a red subpixel RSP (red subpixel), a green subpixel GSP (green subpixel), and a blue subpixel BSP (blue subpixel), for example.

The subpixel RSP emits red (R) light, the subpixel GSP emits green (G) light, and the subpixel BSP emits blue (B) light. In the present embodiment, when there is no particular need to distinguish the subpixel RSP, the subpixel GSP, and the subpixel BSP from one another, these are collectively referred to simply as “subpixel SP”.

Further, the plurality of subpixels SP provided in the pixel region DA may include a plurality of the subpixels SP having the same luminescent color. Hereinafter, a description will be given using an example in which the display device 1 includes the plurality of pixels P each including the subpixels SP of three colors that exhibit the three different colors RGB, respectively, and the plurality of pixels P are provided in a matrix shape in the pixel region DA, as illustrated in FIGS. 1 and 2. Further, hereinafter, a description will be given using an example in which the subpixels SP of the colors RGB are repeatedly arrayed side by side in this order in an extending direction of the gate wiring line GH, and a plurality of the subpixels SP are arrayed side by side for each color along an extending direction of the source wiring line SH, as illustrated in FIGS. 1 and 2. However, the above is merely an example, and the display device 1 may include the subpixels SP other than the subpixels of RGB. Further, the arrays of the subpixels SP are also not limited to the above arrays. Further, hereinafter, a description will be given using an example in which each of the subpixels SP is formed in a rectangular shape. However, the above shape is merely an example, and the shape (outer shape) of the subpixel SP is not limited to the above shape.

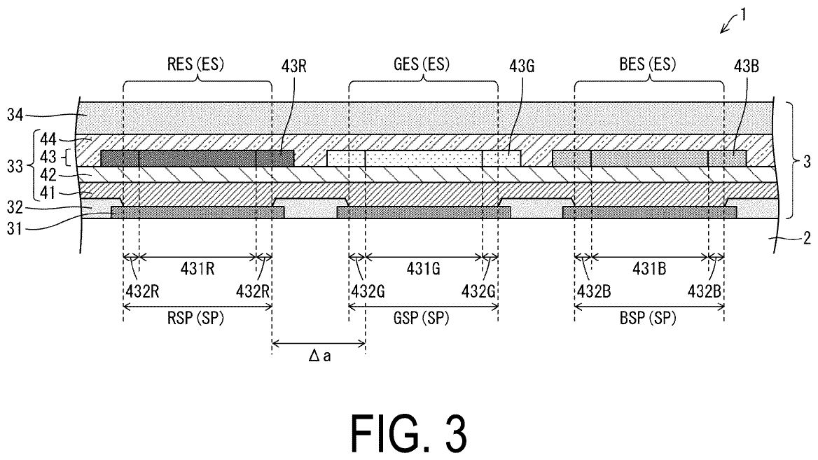

FIG. 3 is a cross-sectional view illustrating an example of a schematic configuration of main portions of the display device 1 according to the present embodiment. Note that FIG. 3 corresponds to a cross section taken along a line A-A′ illustrated in FIG. 2 in the direction of arrows.

As illustrated in FIG. 1, the display device 1 includes a substrate 2 and a light-emitting element layer 3 in this order from the lower layer side. Note that, as an upper layer above the light-emitting element layer 3, a sealing layer (not illustrated) that covers the light-emitting element layer 3 may be provided in order to prevent infiltration of foreign matters, such as moisture, oxygen, and excess organic matters such as dust generated during a manufacturing process, into the light-emitting element layer 3. Further, as an upper layer above the sealing layer, for example, a function film having at least one of an optical compensation function, a touch sensor function, a protection function, a touch panel, a polarizer, or the like may be provided as necessary.

Note that the term “lower layer” refers to a layer formed in a process prior to that of a layer to be compared, and the term “upper layer” refers to a layer formed in a process subsequent to that of a layer to be compared.

The substrate 2 is an array substrate. The substrate 2 has a configuration in which a thin film transistor (TFT) layer is provided on a support substrate. The support substrate is a support body that supports each layer provided on the support substrate. An insulating substrate is used as the support substrate. The support substrate may be, for example, a non-flexible substrate formed of an inorganic material such as glass, or a flexible substrate containing a resin as a main component. When the display device 1 is a top-emitting display device, the support substrate used is not particularly limited. On the other hand, when the display device 1 is a bottom-emitting display device, the support substrate used is a light-transmissive substrate that is transparent or semi-transparent.

A subpixel circuit provided for each of the subpixels SP and a plurality of wiring lines, including the gate wiring line GH and the source wiring line SH, which are connected to these subpixel circuits, are formed in the TFT layer. The subpixel circuit includes a plurality of TFTs for driving a light-emitting element ES described later. These TFTs are electrically connected to the plurality of wiring lines including wiring lines such as the gate wiring line GH and the source wiring line SH. Various known TFTs can be employed as the TFTs. These TFTs and wiring lines are covered with a flattening film that flattens surface irregularities caused by the TFTs and the wiring lines, and the flattening film flattens the surface of the TFT layer. An organic insulating film formed of an acrylic resin or the like is used for the flattening film.

The light-emitting element layer 3 includes a plurality of the light-emitting elements ES provided for each of the subpixels SP, and has a structure in which each layer of the light-emitting elements ES is layered over the substrate 2. In the subpixel RSP, a red light-emitting element (RES) (red light-emitting element) that emits red light is provided as the light-emitting element ES. In the subpixel GSP, a green light-emitting element (GES) (green light-emitting element) that emits green light is provided as the light-emitting element ES. In the subpixel BSP, a blue light-emitting element (BES) (blue light-emitting element) that emits blue light is provided as the light-emitting element ES. Note that, in the present embodiment, when there is no particular need to distinguish the light-emitting element RES, the light-emitting element GES, and the light-emitting element BES from one another, these are collectively referred to simply as “light-emitting element ES”.

The light-emitting element layer 3 includes a plurality of patterned first electrodes, a second electrode, a function layer provided between the first electrodes and the second electrode and including at least a light-emitting layer, and an insulating bank covering the edge of each of the first electrodes.

The first electrode is a lower layer electrode (subpixel electrode) provided in an island shape for each of the light-emitting elements ES (in other words, for each of the subpixels SP) on the substrate 2. The second electrode is an upper layer electrode (common electrode) provided in common to all the light-emitting elements ES (in other words, all the subpixels SP) in an upper layer above the lower layer electrode with the function layer and the bank interposed therebetween.

In the present embodiment, the layers between the first electrodes and the second electrode are collectively referred to as a function layer. The display device 1 may further include a function layer other than the light-emitting layer, such as a hole injection layer, a hole transport layer, an electron injection layer, or an electron transport layer. Note that, hereinafter, the light-emitting layer may be referred to as the “EML”. Further, the hole injection layer will be referred to as “HIL”, and the hole transport layer will be referred to as “HTL”. Further, the electron injection layer will be referred to as “EIL”, and the electron transport layer will be referred to as “ETL”.

One of the first electrode and the second electrode is an anode electrode 31, the other thereof is a cathode electrode 34. Each of the first electrodes is electrically connected to the TFT of the substrate 2.

FIG. 3 illustrates a case, as an example, in which the first electrode is the anode electrode 31, the second electrode is the cathode electrode 34, and the display device 1 includes, in each of the subpixels SP, the anode electrode 31, a function layer 33, and the cathode electrode 34 in this order from the lower layer side. Further, FIG. 3 illustrates a case, as an example, in which the function layer 33 includes, in each of the subpixels SP, an HIL 41, an HTL 42, an EML 43, and an ETL 44 in this order from the lower layer side.

However, the present embodiment is not limited to this example. For example, the display device 1 may include, in each of the subpixels SP, the cathode electrode 34, the function layer 33, and the anode electrode 31 in this order from the lower layer side. In this manner, when the first electrode is the cathode electrode 34 and the second electrode is the anode electrode 31, the layering order of the function layer 33 becomes opposite to that illustrated in FIG. 3. Further, the function layer 33 may include a function layer other than the HIL 41, the HTL 42, the EML 43, and the ETL 44.

The anode electrode 31 is formed of a conductive material and is an electrode that supplies positive holes (holes) to the EML 43 when a voltage is applied. The cathode electrode 34 is formed of a conductive material and is an electrode that supplies electrons to the EML 43 when a voltage is applied.

Of the anode electrode 31 and the cathode electrode 34, the electrode on the light extraction side needs to be light-transmissive. Therefore, at least one of the anode electrode 31 or the cathode electrode 34 is a light-transmissive electrode.

For example, when the display device 1 is a top-emitting display device that emits light from the sealing layer side, a light-transmissive electrode is used for the cathode electrode 34 on the upper layer side, and a so-called reflective electrode having light reflectivity is used for the anode electrode 31 on the lower layer side. On the other hand, when the display device 1 is a bottom-emitting display device that emits light from the substrate 2 side, an opaque electrode or a reflective electrode is used for the cathode electrode 34 on the upper layer side, and a light-transmissive electrode is used for the anode electrode 31 on the lower layer side.

The light-transmissive electrode is formed of a conductive light-transmissive material such as indium tin oxide (ITO), indium zinc oxide (IZO), silver nanowire (AgNW), a thin film of magnesium-silver (MgAg) alloy, or a thin film of silver (Ag), for example.

On the other hand, the reflective electrode is formed of a conductive light-reflective material, for example, a metal such as silver (Ag), aluminum (Al), or copper (Cu), or an alloy including these metals. Note that the reflective electrode may be obtained by layering the above-described light-transmissive material and the above-described light-reflective material.

The bank 32 is an insulating layer having visible light absorbing properties or light shielding properties. The bank 32 is used as an edge cover that covers the edge of the first electrode, and prevents shorting between the first electrode and the second electrode due to thinning of the function layer 33 or a concentration of electric field arising at a pattern end portion of the first electrode. The bank 32 also functions as a subpixel separation film that separates the subpixels SP from each other. The first electrode and at least the EML 43 of the function layer 33 is separated (patterned) into an island shape for each of the subpixels SP by the bank 32. As a result, in the light-emitting element layer 3, the light-emitting element ES including the anode electrode 31, the function layer 33, and the cathode electrode 34 is provided corresponding to each of the subpixels SP.

Examples of a material of the bank 32 include a photosensitive resin to which a light absorbing agent such as carbon black is added. Examples of the above-described photosensitive resin include an organic insulating material such as polyimide and an acrylic resin.

The bank 32 has a tapered cross section in a cross-sectional view. In other words, the bank 32 has a reverse-tapered opening in a cross-sectional view, the opening size (diameter) of which decreases toward the lower side. When θ (°) is defined as an angle (inclination angle) formed by an inclined face (in other words, an inclined opening sidewall) of the bank 32 and the lower face (bottom face) of the bank 32, θ is preferably 10°≤θ≤90°, and more preferably 30°≤θ≤80°. As a result, it is possible to prevent step disconnection of the upper layer while reducing manufacturing defects of the bank 32.

The HIL 41 is a layer that has hole transport properties and promotes injection of positive holes from the anode electrode 31 into the HTL 42 or the EML 43. A known hole transport material can be used for the HIL 41. Examples of the hole transport material used for the HIL 41 include a composite (abbreviated “PEDOT:PSS”) of poly (3,4-ethylenedioxythiophene) (PEDOT) and polystyrene sulfonic acid (PSS), nickel oxide (NiO), and copper thiocyanate (CuSCN). Note that only one type of these hole transport materials may be used, or two or more types thereof may be mixed and used as appropriate.

The HTL 42 is a layer that has hole transport properties and transports the positive holes injected from the HIL 41 to the EML 43. A known hole transport material can be used for the HTL 42. Examples of the hole transport material used for the HTL 42 include poly[(9,9-dioctylfluorenyl-2,7-diyl)-co-(4,4′-(N-4-sec-butylphenyl)) diphenylamine)] (abbreviated “TFB”), poly [N,N′-bis(4-butylphenyl)-N,N′-bis (phenyl)-benzidine] (abbreviated “p-TPD”), and polyvinyl carbazole (abbreviated “PVK”). Only one type of these hole transport materials may be used, or two or more types thereof may be mixed and used as appropriate.

The ETL 44 is a layer that has electron transport properties and transports electrons from the cathode electrode 34 to the EML 43. A known electron transport material can be used for the ETL 44. Examples of the electron transport material used for the ETL 44 include zinc oxide (ZnO) and magnesium zinc oxide (MgZnO). Only one type of these electron transport materials may be used, or two or more types thereof may be mixed and used as appropriate.

The EML 43 is a layer that emits light as a result of an occurrence of recombination between the positive holes transported from the anode electrode 31 and the electrons transported from the cathode electrode 34.

The light-emitting element RES includes, as the EML 43, an island-shaped EML 43R (red EML) that emits red light. The light-emitting element GES includes, as the EML 43, an island-shaped EML 43G (green EML) that emits green light. The light-emitting element BES includes, as the EML 43, an island-shaped EML 43B (blue EML) that emits blue light. In the present embodiment, when there is no particular need to distinguish the EML 43R, the EML 43G, and the EML 43B, from one another, these are collectively referred to simply as “EML 43”

Note that the blue light refers to, for example, light having an emission peak wavelength in a wavelength band of 400 nm or greater and 500 nm or less. The green light refers to, for example, light having an emission peak wavelength in a wavelength band of 500 nm or greater and 600 nm or less. Further, the red light refers to light having an emission peak wavelength in a wavelength band of 600 nm or greater and 780 nm or less.

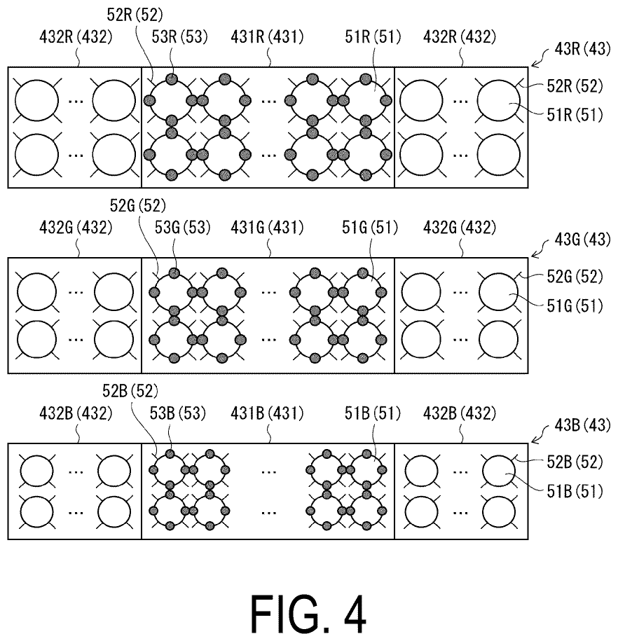

FIG. 4 is an enlarged cross-sectional view schematically illustrating a part of the EML 43 of each color according to an example of the display device 1 according to the present embodiment.

The light-emitting element ES according to the present embodiment is a quantum dot light emitting diode (QLED). Therefore, as illustrated in FIG. 4, the EML 43 is a quantum dot light-emitting layer including, as a light-emitting material, nano-sized quantum dots (hereinafter, denoted by “QDs”) 51 corresponding to the luminescent color.

The EML 43R includes QDs 51R (red QDs) that emit red light, as a red light-emitting material. The EML 43G includes QDs 51G (green QDs) that emit green light, as a green light-emitting material. The EML 43B includes QDs 51B (blue QDs) that emit blue light, as a blue light-emitting material. Note that in the present embodiment, when there is no particular need to distinguish the QD 51R, the QD 51G, and the QD 51B from one another, these are collectively referred to simply as “QD 51”.

The QD 51 used in the present embodiment is not particularly limited, and various known QDs can be used.

Note that in the disclosure, the QD is a dot having a maximum width of 100 nm or less. Since the QD emits fluorescence and is nano order in size, the QD may also be referred to as a fluorescent nanoparticle or a QD phosphor particle. Further, since the composition of the QD is derived from a semiconductor material, the QD may also be referred to as a semiconductor nanoparticle. Further, since the QD has a specific crystal structure, the QD may also be referred to as a nanocrystal.

The shape of the QD 51 is not particularly limited as long as it is within a range satisfying the maximum width, and the shape thereof is not limited to a spherical three-dimensional shape (circular cross-sectional shape). The shape of the quantum dot may be, for example, a polygonal cross-sectional shape, a rod-shaped three-dimensional shape, a branch-shaped three-dimensional shape, or a three-dimensional shape having unevenness on the surface thereof, or a combination thereof.

The QD 51 may include, for example, a semiconductor material constituted by at least one element selected from the group consisting of cadmium (Cd), sulfur(S), tellurium (Te), selenium (Se), zinc (Zn), indium (In), nitrogen (N), phosphorus (P), arsenic (As), antimony (Sb), aluminum (Al), gallium (Ga), lead (Pb), silicon (Si), germanium (Ge), and magnesium (Mg).

Further, as an example, the QD 51 may have a core-shell structure including a core and a shell, or may be of a core-shell type or a core-multi shell type. In a case in which the QD 51 includes the shell, it is sufficient for the shell to be provided on the surface of the core. Although it is desirable for the shell to cover the entire core, the shell need not necessarily completely cover the core. Further, the QD 51 may be a two-component core type, a three-component core type, or a four-component core type. An emission wavelength of the QD 51 can be changed in various ways depending on the particle size, the composition, or the like thereof.

As illustrated in FIG. 4, numerous ligands are coordinated, as ligands, in the vicinity of the surface of the QD 51. Note that in FIG. 4, the numbers of the QDs 51 and the ligands are reduced for convenience of illustration.

By coordinating the ligands to the surfaces of the QDs 51, aggregation of the QDs 51 can be suppressed, and thus intended optical characteristics are easily realized. The “ligand” is a compound having a function to coordinate, and when both the ligand and the QD 51 are included, it is assumed that at least a portion of the ligand is coordinated to the QD 51. Further, the “coordination” means that the ligand is adsorbed on the surface of the QD 51, or the ligand is present in the vicinity of the QD 51 (in other words, the ligand modifies the surface of the QD 51 (surface modification)). Therefore, as in the above description of the ligand, when both the ligand and the QD 51 are included, it is assumed that at least a portion of the ligand is coordinated to the QD 51. Further, the “adsorption” means that a concentration of the ligand on the surface of the QD 51 is higher than that in the surroundings. The above-described adsorption may be chemical adsorption in which there is a chemical bond between the QD 51 and the ligand, physical adsorption, or electrostatic adsorption. As long as the ligand has a chemical effect on the surface of the QD 51 due to the adsorption, the ligand may be bonded by a coordination bond, a common bond, an ionic bond, a hydrogen bond, or the like, or the ligand need not necessarily be bonded. As described above, in the present embodiment, not only a molecule or an ion coordinated to the surface of the QD 51 but also a molecule or an ion that can be coordinated but is not coordinated is referred to as a “ligand”.

In this manner, the ligand is provided on the surface of each of the QDs 51. Thus, each of the EMLs 43 includes the ligand. Each of the EMLs 43 includes an organic ligand 52 and an inorganic ligand 53 as the ligand.

As illustrated in FIGS. 2 and 4, the EML 43R according to the present embodiment includes a first region 431R and a second region 432R having different numbers of inorganic ligands 53R contained per unit volume. Similarly, the EML 43G according to the present embodiment includes a first region 431G and a second region 432G having different numbers of inorganic ligands 53G contained per unit volume. The EML 43B according to the present embodiment includes a first region 431B and a second region 432B having different numbers of inorganic ligands 53B contained per unit volume.

The first region 431R includes the QD 51R and, of an organic ligand 52R and an inorganic ligand 53R, at least the inorganic ligand 53R, and is a region in which the number of the inorganic ligands 53R contained per unit volume is greater than the number of the inorganic ligands 53R contained per unit volume in the second region 432R. The second region 432R includes the QD 51R and, of the organic ligand 52R and the inorganic ligand 53R, at least the organic ligand 52R, and the number of the inorganic ligands 53R contained per unit volume is less than the number of the inorganic ligands 53R contained per unit volume in the first region 431R.

The first region 431G includes the QD 51G and, of an organic ligand 52G and an inorganic ligand 53G, at least the inorganic ligand 53G, and is a region in which the number of the inorganic ligands 53G contained per unit volume is greater than the number of the inorganic ligands 53G contained per unit volume in the second region 432G. The second region 432G includes the QD 51G and, of the organic ligand 52G and the inorganic ligand 53G, at least the organic ligand 52G, and is a region in which the number of the inorganic ligands 53G contained per unit volume is less than the number of the inorganic ligands 53G contained per unit volume in the first region 431G.

The first region 431B includes the QD 51B and, of an organic ligand 52B and an inorganic ligand 53B, at least the inorganic ligand 53B, and is a region in which the number of the inorganic ligands 53B contained per unit volume is greater than the number of the inorganic ligands 53B contained per unit volume in the second region 432B. The second region 432B includes the QD 51B and, of the organic ligand 52B and the inorganic ligand 53B, at least the organic ligand 52B, and is a region in which the number of the inorganic ligands 53B contained per unit volume is less than the number of the inorganic ligands 53B contained per unit volume in the first region 431B.

Note that FIG. 4 illustrates a case, as an example, in which none of the second region 432R, the second region 432G, and the second region 432B includes the inorganic ligand. In this manner, the number of the inorganic ligands 53R contained per unit volume of the second region 432R includes a case in which the number of the inorganic ligands 53R contained per unit volume of the second region 432R is 0. Similarly, the number of inorganic ligands 53G contained per unit volume of the second region 432G includes a case in which the number of the inorganic ligands 53G contained per unit volume of the second region 432G is 0. Further, the number of the inorganic ligands 53B contained per unit volume of the second region 432B includes a case in which the number of the inorganic ligands 53B contained per unit volume of the second region 432B is 0.

Further, FIG. 4 illustrates a case, as an example, in which each of the first region 431R, the first region 431G, and the first region 431B includes the organic ligand 52 and the inorganic ligand 53 as the ligand. Hereinafter, a case will be described, as an example, in which each of the first region 431R, the first region 431G, and the first region 431B includes both the organic ligand 52 and the inorganic ligand 53 as the ligand. However, the present embodiment is not limited to this example, and as described above, the first region 431R, the first region 431G, and the first region 431B may include the QD 51 and at least the inorganic ligand 53 of the organic ligand 52 and the inorganic ligand 53.

In the present embodiment, when there is no particular need to distinguish the first region 431R, the first region 431G, and the first region 431B from one another, these are collectively referred to simply as “first region 431”. Similarly, in the present embodiment, when there is no particular need to distinguish the second region 432R, the second region 432G, and the second region 432B from one another, these are collectively referred to simply as “second region 432”.

Further, in the present embodiment, when there is no particular need to distinguish the organic ligand 52R, the organic ligand 52G, and the organic ligand 52B from one another, these are collectively referred to simply as “organic ligand 52”, as described above. Similarly, in the present embodiment, when there is no particular need to distinguish the inorganic ligand 53R, the inorganic ligand 53G, and the inorganic ligand 53B from one another, these are collectively referred to simply as “inorganic ligand 53”, as described above. The organic ligand 52R, the organic ligand 52G, and the organic ligand 52B may be the same ligand or different ligands. Further, the inorganic ligand 53R, the inorganic ligand 53G, and the inorganic ligand 53B may be the same ligand or may be different ligands.

As the organic ligand 52, a ligand having at least one coordinating functional group capable of being coordinated to the QD 51 is used, and various known organic ligands can be used.

Representative examples of the coordinating functional group include at least one functional group selected from the group consisting of a thiol group, an amino group, a carboxyl group, a phosphonic group, and a phosphine group.

The organic ligand 52 is not particularly limited, and representative examples thereof include amine-based, fatty acid-based, thiol-based, phosphine-based, phosphine oxide-based, and alcohol-based ligands. Examples of such an organic ligand include oleylamine, oleic acid, dodecanthiol, trioctylphosphine, trioctylphosphine oxide, tributylphosphine oxide, and oleyl alcohol, but the organic ligand is not particularly limited to these examples.

Note that the QD is commercially available, and the commercially available QD is generally provided in the form of a QD dispersion including an organic ligand. The QD can be synthesized by any method. For example, a wet method is used for the synthesis of the QD, and the particle size of the QD is controlled by coordinating an organic ligand to the surface of the QD. Note that the organic ligand is used as a dispersing agent for improving dispersibility of the QD in the QD dispersion, and is also used for improving surface stability and storage stability of the QD.

Thus, the organic ligand 52 may be an organic ligand coordinated to the QD that has been synthesized or commercially obtained to be the QD 51, or may be a desired organic ligand replaced by ligand substitution or the like.

On the other hand, the inorganic ligand has higher stability than the organic ligand, and can stably protect the surface of the QD. Further, the inorganic ligand is superior to the organic ligand having a long hydrocarbon chain, in terms of current injection into the QD, and facilitates carrier transport between the individual QDs.

The inorganic ligand 53 used in the present embodiment is not particularly limited, and various known inorganic ligands can be used. Examples of the inorganic ligand 53 include inorganic anions such as F⁻, Cl⁻, Br⁻, I⁻, S²⁻, Se²⁻, Te²⁻, HS⁻, SNS₄⁴⁻, and Sn₂S₆⁴⁻. Since these inorganic anions are negatively charged, they are attracted as ligands to the positively charged surface of the QD 51.

Among the above-described inorganic anions, anions composed of inorganic monoatomic ions such as F⁻, Cl⁻, Br⁻, I⁻, S²⁻, Se²⁻ and Te²⁻ are more preferable than anions composed of inorganic polyatomic ions, because of their higher stability. Further, among them, ions of halogen atoms called halogen ligands such as F⁻, Cl⁻, Br⁻, and I⁻ are more preferable because of high stability and high current injection properties, and among them, fluoride ions (ions of fluorine atoms) represented by F⁻ are particularly preferable. F (fluoride) has particularly high electro-negativity and is unlikely to be desorbed from the QD 51, and thus can strongly protect the QD 51.

As illustrated in FIG. 2, each of the EMLs 43 according to the present embodiment is constituted by the first region 431 and the second region 432. In each of the subpixels SP, a region in the EML 43 other than the second region 432 is the first region 431.

In the present embodiment, the second region 432 surrounds the first region 431 in a frame shape. Thus, the first region 431 of each of the EMLs 43 in each of the subpixels SP includes a central portion of each of the EMLs 43 in each of the subpixels SP. Note that in the present embodiment, the “central portion of each of the EMLs 43 in each of the subpixels SP” refers to the center of gravity of each of the EMLs 43 in each of the subpixels SP.

Further, the second region 432 of each of the EMLs 43 in each of the subpixels SP includes all end portions of each of the EMLs 43 adjacent to other subpixels SP. Therefore, in the present embodiment, the second region 432 of each of the EMLs 43 in each of the subpixels SP includes end portions of the EML 43 adjacent to the subpixels SP having the same luminescent color as that of the subpixel SP provided with that EML, and end portions adjacent to the subpixels SP having different luminescent colors from that of the subpixel SP provided with that EML.

As illustrated in FIG. 3, when Aa is a shortest distance from an end portion of the other subpixel SP adjacent to the second region 432 of the EML 43 of each of the subpixels SP to an end portion of the first region 431 of that EML 43, the first region 431 is set such that Δa is within a range of 2.0 μm or more and 8.5 μm or less.

That is, when the subpixel SP adjacent to the light-emission target subpixel SP, which is originally intended to be caused to emit light, is defined as the reference subpixel SP, when the first region 431 and the second region 432 are not provided in the reference subpixel SP, there is a possibility that light is undesirably emitted from a region, of the reference subpixel SP, within a range of the distance Aa from an end portion of the adjacent subpixel SP, due to a leakage current from the light-emission target subpixel SP adjacent to the reference subpixel SP.

Therefore, in the present embodiment, a position in the reference subpixel SP away from the end portion of the adjacent subpixel SP by Aa is defined as a boundary position between the first region 431 and the second region 432 of the reference subpixel SP, and a region of the reference subpixel SP inside a boundary line connecting the boundary positions is defined as the first region 431 of the reference subpixel SP. Further, a region outside the boundary line is defined as the second region 432 of the reference subpixel SP. Note that the region inside the boundary line refers to a region including a central portion of the reference subpixel SP and sandwiched between two of the boundary positions inside the reference subpixel SP.

In this manner, in the present embodiment, a region in which the QD 51 is not caused to emit light due to the leakage current from the adjacent subpixel SP even when the QD 51 includes the inorganic ligand 53 is defined as the first region 431. As described above, in the first region 431, even when the inorganic ligand 53 is included, the QD 51 does not emit light due to the leakage current from the adjacent subpixel SP. Thus, by increasing an amount of the inorganic ligands 53 per unit volume, the QD 51 can be stably protected by the inorganic ligand 53, and also the current injection properties can be improved.

On the other hand, in the second region 432 outside the first region 431 and including the end portions adjacent to the other subpixels SP, by causing the amount of the inorganic ligands 53 per unit volume to be less than that in the first region 431, it is possible to suppress the light emission of the QD 51 due to the leakage current from the adjacent subpixel SP.

As a result, it is possible to improve the light emission efficiency by the inorganic ligand 53, and further, it is possible to suppress the light emission due to the leakage current from the adjacent subpixels SP and to suppress an occurrence of optical crosstalk such as color mixing or formation of an unclear image. Accordingly, it is possible to reduce the light emission of the subpixel SP due to the leakage current, and thus to display a high-resolution image.

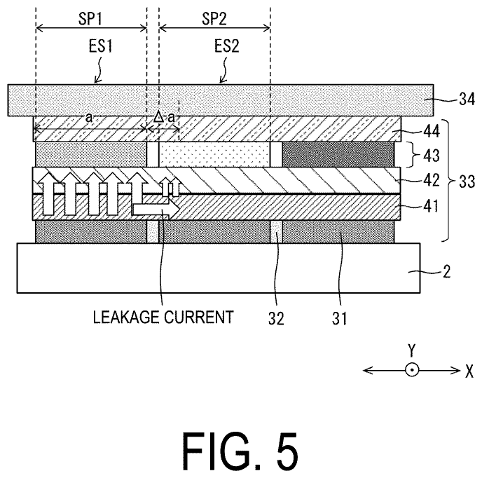

More details will be described below. FIG. 5 is a cross-sectional view illustrating a leakage current between a first subpixel SP1 and a second subpixel SP2 of a display device for comparison in which the first region 431 and the second region 432 are not provided in the EML 43 of the display device 1 illustrated in FIGS. 2 and 3.

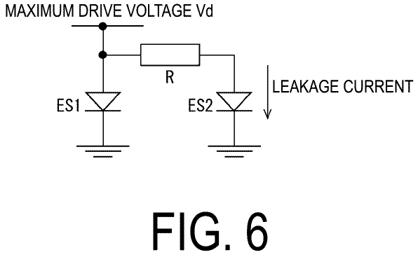

Note that FIG. 5 schematically illustrates, in a simplified manner, a cross-sectional configuration of the display device for comparison in which the first region 431 and the second region 432 are not provided in the EML 43 illustrated in FIG. 3. A cross section illustrated in FIG. 5 corresponds to the cross section taken along the line A-A′ illustrated in FIG. 2. Further, FIG. 6 is a circuit diagram illustrating the leakage current between the first subpixel SP1 and the second subpixel SP2 of the display device for comparison illustrated in FIG. 5. As illustrated in FIGS. 5 and 6, a light-emitting element ES1 is provided in the first subpixel SP1, and a light-emitting element ES2 is provided in the second subpixel SP2.

Hereinafter, a leakage current flowing from the first subpixel SP1 to the second subpixel SP2 when the first region 431 and the second region 432 are not provided in the EML 43, as illustrated in FIGS. 5 and 6, will be discussed.

Hereinafter, the subpixel width of each of the subpixels SP is denoted by a, and the depth of each of the subpixels SP is denoted by b. In FIG. 5, a represents the width of the subpixel SP in the X-axis direction (row direction) which is one of the horizontal axes, and b represents the width of the subpixel SP in the Y-axis direction (column direction) orthogonal to the X-axis direction in the horizontal plane.

Further, as illustrated in FIG. 5, a width, in the X-axis direction, from an end portion of the first subpixel SP1 to a position at which the second subpixel SP2 emits light due to the leakage current from the first subpixel SP1 is denoted by Δa. That is, the distance Δa from the end portion of the first subpixel SP1 is the above-described Δa.

Then, as illustrated in FIG. 6, the maximum drive voltage of the first subpixel SP1 is denoted by Vd. Further, the light-emission threshold voltage of the second subpixel SP2 is denoted by Vth, and the current density of the leakage current is denoted by j. Further, when the conductivity of the HIL 41 is σ, the thickness of the HIL 41 is t, and the resistance due to the HIL 41 is R, R satisfies R=Δa/(σ×b×t), and when the voltage applied to the second subpixel SP2 is equal to the light-emission threshold voltage Vth, Vd−RjbΔa=Vth is established. By converting this equation, the following equation (1) is obtained.

$$Δ a = √ ( ( Vd - Vth ) \times σ \times t / j \qquad ( 1 )$$

Here, σ=10⁻⁶ to 10⁻⁵ S/cm, and t=40 nm. Then, when the first subpixel SP1 and the second subpixel SP2 are the subpixels SP of the same color, and Vd−Vth=1V and j=0.1 mA/cm² between the subpixels SP of the same color, Δa=2.0 to 6.3 μm is satisfied between the subpixels SP of the same color. Further, when one of the first subpixel SP1 and the second subpixel SP2 is the subpixel RSP and the other is the subpixel BSP, and Vd−Vth=1.8 V and j=0.1 mA/cm² between the subpixel RSP and the subpixel BSP, Δa=2.7 to 8.5 μm is satisfied between the subpixel RSP and the subpixel BSP.

Further, when one of the first subpixel SP1 and the second subpixel SP2 is the subpixel GSP and the other is the subpixel BSP, and Vd−Vth=1.5 V and j=0.1 mA/cm² between the subpixel GSP and the subpixel BSP, Δa=2.4 to 7.7 μm is satisfied between the subpixel GSP and the subpixel BSP. Further, when one of the first subpixel SP1 and the second subpixel SP2 is the subpixel RSP and the other is the subpixel GSP, and Vd−Vth=1.3 V and j=0.1 mA/cm² between the subpixel RSP and the subpixel GSP, Δa=2.3 to 7.2 μm is satisfied between the subpixel RSP and the subpixel GSP.

Thus, the shortest distance from the end portion of the other subpixel SP adjacent to the second region 432 of the EML 43 of the reference subpixel SP, to the end portion of the first region 431 of the reference subpixel SP is desirably set such that the range of Δa is within the above-described range of Δa in accordance with the luminescent color of the reference subpixel SP and the luminescent color of the subpixel SP adjacent to the reference subpixel SP. As a result, in addition to the reduction of the leakage current, the amount of the inorganic ligands 53 to be used can be made a necessary minimum amount, and the material cost can be reduced. However, by setting the above-described Δa to be the same regardless of the luminescent color of the reference subpixel SP and the luminescent color of the subpixel SP adjacent to the reference subpixel SP, design and manufacturing become easier.

Next, a preferable ratio of the inorganic ligands 53 to the total number of the organic ligands 52 and the inorganic ligands 53 in the first region 431 will be described.

The inorganic ligand 53 has higher stability than the organic ligand 52, and is excellent in current injection properties. Thus, as described above, it is sufficient that the first region 431 includes, as the ligand, at least the inorganic ligand 53 of the organic ligand 52 and the inorganic ligand 53. Therefore, the ratio of the inorganic ligands 53 to the total number of the organic ligands 52 and the inorganic ligands 53 in the first region 431 may be 100%. In other words, the first region 431 may include only the inorganic ligand 53 of the organic ligand 52 and the inorganic ligand 53. Note that a case in which the first region 431 includes only the inorganic ligand 53 as the ligand will be described in an embodiment to be described later. However, in order to prevent the aggregation of the QDs 51, it is preferable that the first region 431 include the organic ligand 52.

Therefore, the maximum ratio of the inorganic ligands 53 preferable for preventing the aggregation of the QDs 51 is calculated.

When the particle size of the QD 51 is, for example, 3 nm, assuming that QD is spherical, the surface area of the QD 51 calculated from the particle size of the QD 51 is 28 nm². In a case in which the inorganic ligand 53 is, for example, F⁻, the ligand diameter of the inorganic ligand 53 is represented by twice the ionic radius of F⁻, and thus is 0.26 nm. Further, when the area occupied by one of the inorganic ligands 53 is calculated from the ligand diameter of the inorganic ligand 53, 0.05 nm² is obtained when the inorganic ligand 53 is, for example, F⁻.

The number of the inorganic ligands 53 contained in each of the QDs 51 can be obtained by dividing the surface area of the QD 51 by the area occupied by one of the inorganic ligands 53. Therefore, in the case of this example, the number of the inorganic ligands 53 contained in each of the QDs 51 is 533.

Further, the number of the organic ligands 52 contained in each of the QDs 51 is considered. When the EML 43 is filled to a maximum density, for each one of the QDs 51, 12 of the QDs 51 are in close proximity thereto. In general, the organic ligand easily become detached by environmental factors such as heat and a coating process. For this reason, in order to prevent the aggregation of the QDs 51, it is desirable that about 10 of the organic ligands 52 are present for each of the QDs 51 in close proximity. In this case, the number of the organic ligands 52 for each of the QDs 51 is 120.

Thus, the maximum ratio of the inorganic ligands 53 to the total number of the organic ligands 52 and the inorganic ligands 53 (i.e., the number of the inorganic ligands 53/(the number of the inorganic ligands 53+the number of the organic ligands 52)) preferable for preventing the aggregation of the QDs 51 is 82%.

In the first region 431, as the amount of the inorganic ligands 53 increases, the amount of the organic ligands 52 coordinated to the QD 51 decreases, and the current injection becomes easier. On the other hand, when the ratio of the inorganic ligands 53 to the total number of the organic ligands 52 and the inorganic ligands 53 in the second region 432 located in a subpixel peripheral portion is reduced (i.e., when the ratio of the organic ligands 52 is increased), it becomes difficult for carriers to be injected into the QDs 51 in the subpixel peripheral portion. Thus, when a light-emission threshold voltage of a subpixel central portion, which forms the first region 431, is Vth1, and a light-emission threshold voltage of the subpixel peripheral portion, which forms the second region 432, is Vth2, Vth2 becomes higher than Vth1.

According to experimental results, when the inorganic ligands 53 were not added (i.e., when the ratio of the inorganic ligands 53 was 0%), the light-emission threshold voltage Vth2 was increased by approximately 2 V as compared with the light-emission threshold voltage Vth1 obtained when the inorganic ligands 53 were added up to the ratio of the inorganic ligands 53 described above (82%).

When the ratio of the inorganic ligands 53 to the total number of the organic ligands 52 and the inorganic ligands 53 is r, an increased amount V(r) of the light-emission threshold voltage Vth2 (light emission threshold voltage increase amount) is determined by the difficulty of the current injection into the QD 51 (ratio of the organic ligands 52 to the surface area of the QD 51). Note that, here, V(r)=Vth2−Vth1 is established, and V(r) is linear with respect to the above-described ratio of the organic ligands 52. Thus, V(r) is linear with respect to r. Therefore, V(r) [unit: V] is calculated by the following equation (2).

$$V ( r ) = 2.44 \times ( 0 \text{.82} - r ) \qquad ( 2 )$$

It is desirable that V(r) is 1 V or greater so that the subpixel peripheral portion of the reference subpixel SP does not emit light due to driving of the light-emission target subpixel SP adjacent to the reference subpixel SP. Here, when the maximum drive voltage of each of the subpixels SP is Vdm and the light-emission threshold voltage of each of the subpixels SP is Vth, 1 V represents a difference between Vdm and Vth, and more specifically, represents the difference (Vdm−Vth) between the maximum drive voltage (Vdm) of the light-emission target subpixel SP, adjacent to the reference subpixel SP, and the light-emission threshold voltage (Vth) of the reference subpixel SP.

Note that in the present embodiment, the light-emission threshold voltage refers to a voltage at which the light-emitting element ES starts to emit light when the voltage applied to the light-emitting element ES is increased (e.g., a voltage at which the light-emitting element emits light at 1 cd/m²). In an ideal case in which the element structures of the HTL 42, the ETL 44, and the like are optimized, the light-emission threshold voltage is a value obtained by converting a band gap (Eg) of the QD 51 into a voltage.

For example, when the emission peak wavelength (λ) of the subpixel RSP is 620 nm and Eg=2.0 eV, the light-emission threshold voltage of the subpixel RSP is ideally 2.0 V. Further, when the emission peak wavelength (λ) of the subpixel GSP is 530 nm and Eg=2.3 eV, the light-emission threshold voltage of the subpixel GSP is ideally 2.3 V. Further, when the emission peak wavelength (λ) of the subpixel BSP is 450 nm and Eg=2.8 eV, the light-emission threshold voltage of the subpixel BSP is ideally 2.8 V.

When the current injection is inhibited due to a great amount of the organic ligands 52 or the like, the light-emission threshold voltage becomes high, and unless a high voltage is applied, the current cannot be injected into the QD 51, and thus light cannot be emitted.

Further, the maximum drive voltage is a voltage that causes the light-emitting element ES to emit light at the maximum luminance (e.g., 100 cd/m²) specified in the display device specifications, and is generally equal to the light-emission threshold voltage +1 V. Therefore, Vdm−Vth=1 V is established. Each of the light-emitting elements ES in the display device 1 is driven at a voltage equal to or higher than the light-emission threshold voltage (Vth) and equal to or lower than the maximum drive voltage (Vdm).

When the maximum drive voltage (Vd) leaking from the light-emission target subpixel SP adjacent to the reference subpixel SP exceeds the light-emission threshold voltage (Vth) of the reference subpixel SP, light emission caused by the leakage current occurs due to the current corresponding to an amount of the voltage by which the maximum drive voltage (Vd) has exceeded the light-emission threshold voltage (Vth).

Therefore, a potential difference between the light-emission target subpixel SP adjacent to the reference subpixel SP and the reference subpixel SP is obtained from a difference (Vdm−Vth) between the maximum drive voltage (Vdm) of the light-emission target subpixel SP adjacent to the reference subpixel SP and the light-emission threshold voltage (Vth) of the reference subpixel SP, and the leakage current is estimated from the potential difference and the conductivity of the HIL 41. The amount (ratio) of the inorganic ligands 53 in a region of a range in which the potential difference exceeds the light-emission threshold voltage (Vth) of the reference subpixel SP is reduced, and the light-emission threshold voltage (Vth) of the reference subpixel SP is increased. Note that, here, the region of the range in which the potential difference exceeds the light-emission threshold voltage (Vth) of the reference subpixel SP is a region in which the value of the current density of the leakage current exceeds 0.1 mA/cm², and is a region having a width of Δa, the width being measured using an end portion of the subpixel SP adjacent to the reference subpixel SP as the base point.

Note that the light-emission threshold voltage (Vth) in this case is a value obtained when the disclosure is not applied (i.e., a value obtained when the inorganic ligands 53 are uniformly contained in the reference subpixel SP). Therefore, Equation (2) described above was used to define to what extent the light-emission threshold voltage (Vth) increases due to a change in the amount of the inorganic ligands 53 when the disclosure is applied as compared with the case in which the disclosure is not applied. As described above, the light-emission threshold value increase amount (V(r)) needs to be at least 1 V or greater (i.e., V(r)≥1).

In order to satisfy the above, it is desirable that r≤0.41, and it is desirable that the ratio (r) of the inorganic ligands 53 to the total number of the organic ligands 52 and the inorganic ligands 53 in the second region 432 of the EML 43 in the subpixel peripheral portion is 0% or more and 41% or less.

Further, since the maximum drive voltage (Vdm) is different depending on the subpixel SP of each color, it is desirable to define the light emission threshold increase amount (V(r)) in consideration of the difference in the maximum drive voltage (Vd). As described above, the difference in the band gap (Eg) of the QD 51 between the adjacent subpixels SP, and the difference in the light-emission threshold voltage obtained by converting the band gap (Eg) into the voltage become greatest between the subpixel RSP and the subpixel BSP. Therefore, it is more desirable that the light emission threshold increase amount V(r) is 1.8 V (i.e., 1+0.8 V) or greater (V(r)≥1.8) in consideration of the maximum drive voltage difference 0.8 V due to the light-emission threshold voltage difference (0.8 V) between the subpixel RSP and the subpixel BSP, in addition to 1 V described above. Then, when the ratio (r) of the inorganic ligands 53 to the total number of the organic ligands 52 and the inorganic ligands 53 is defined using these conditions, it is desirable that r≤0.082. Therefore, in this case, it is desirable that the ratio (r) of the inorganic ligands 53 to the total number of the organic ligands 52 and the inorganic ligands 53 in the second region 432 of the EML 43 in the subpixel peripheral portion is 0% or more and 8.2% or less.

Therefore, it is preferable that the ratio (r) of the inorganic ligands 53 to the total number of the organic ligands 52 and the inorganic ligands 53 in the first region 431 of the EML 43 in the subpixel central portion be 8.2% or more and 100% or less, and more preferably 8.2% or more and 82% or less. Further, it is even more preferable that the ratio (r) of the inorganic ligands 53 to the total number of the organic ligands 52 and the inorganic ligands 53 in the first region 431 be 41% or more and 82% or less.

Note that the ratio (r) of the inorganic ligands 53 in the first region 431 and the ratio (r) of the inorganic ligands 53 in the second region 432 can be appropriately set (selected) within the above-described range. However, a combination in which the ratio (r) of the inorganic ligands 53 is equal in the first region 431 and the second region 432, or the ratio (r) of the inorganic ligands 53 is greater in the second region 432 than in the first region 431 is excluded.

The formation of the first region 431 and the second region 432 in the EML 43 can be confirmed by examining the distribution of the inorganic ligands 53 in the EML 43 by the cross-sectional scanning electron microscope-energy dispersive X-ray spectrometry (SEM-EDX). Further, the number of the inorganic ligands 53 per unit volume in each of the first region 431 and the second region 432 can be determined by the cross-sectional SEM-EDX. Note that since the inorganic ligand 53 such as halogen has a strong coordination force, if the inorganic ligand 53 is present in the EML 43, it can be assumed that the inorganic ligand 53 is coordinated to the QD 51.

According to the present embodiment, by providing the first region 431 and the second region 432 in the EML 43 as described above, it is possible to achieve both improvement in the light emission efficiency by the inorganic ligand 53 and suppression of the light emission caused by the leakage current from the adjacent subpixel SP, and further, it is possible to narrow the interval between the subpixels SP.

When the light-emitting element ES, which is the QLED (nano LED), is used in the display device 1, the narrowing of the interval between the subpixels SP has a significant effect. For example, by narrowing the interval between the subpixels SP, it is possible to increase the area of the subpixel SP in the pixel P having the same area. As a result, the light emission luminance of the subpixel SP and the pixel P is increased, and thus the brighter display device 1 can be realized. Further, when the area of the subpixel SP is constant and the number of pixels of the display device 1 is constant, the area of the display device 1 can be reduced by narrowing the interval between the subpixels SP, and it is possible to achieve reduction in manufacturing costs, weight reduction of the display device 1, and the like. Further, when the area of the subpixel SP is constant and the area of the display device 1 is constant, it is possible to increase the number of pixels of the display device 1 by narrowing the interval between the subpixels SP, and an increase in the resolution of an image is expected.

However, although the above-described advantages are realized by narrowing the interval between the subpixels SP, light emission caused by the leakage current from the adjacent subpixel SP becomes a problem. When unintended light emission of the subpixel SP occurs, the optical crosstalk such as color mixing or formation of an unclear image occurs. Such crosstalk causes deterioration in display quality of the display device.

According to the present embodiment, as described above, by providing the above-described first region 431 and second region 432 in the EML 43, it is possible to suppress the occurrence of the above-described optical crosstalk even when the interval between the subpixels SP is narrowed. Therefore, according to the present embodiment, it is possible to achieve both the improvement in the light emission efficiency by the inorganic ligand 53 and the suppression of the light emission caused by the leakage current from the adjacent subpixel SP, and further, it is possible to narrow the interval between the subpixels SP and provide the display device 1 having excellent display quality.

Note that the display device 1 may include a first subpixel (e.g., subpixel RSP) and a second subpixel (e.g., subpixel GSP) adjacent to the first subpixel in a first direction (e.g., lateral direction or row direction), and may have a configuration in which the first subpixel includes an anode (anode electrode 31), a cathode (cathode electrode 34), and a first light-emitting layer (for example, EML 43R) located between the anode and the cathode and including the QD 51 and the inorganic ligand 53 (e.g., halogen ligand), the first light-emitting layer includes a first end portion (e.g., a right-side portion, of the second region 432R, extending in the vertical direction (column direction)), a central portion (e.g., at least a portion of the first region 431R), and a second end portion (e.g., a left-side portion, of the second region 432R, extending in the vertical direction) arranged in the first direction, and the number of the inorganic ligands 53 per unit volume of the first end portion is less than the number of the inorganic ligands 53 per unit volume of the central portion. Further, the second subpixel (e.g., subpixel GSP) may be adjacent to the first end portion, and may emit light of a different color (e.g., a green wavelength region having a shorter wavelength than that of the red light-emitting first subpixel) from that of the first subpixel (e.g., subpixel RSP).

### Manufacturing Method for Display Device 1

Next, a manufacturing method for the display device 1 according to the present embodiment will be described using a manufacturing method for the display device 1 illustrated in FIG. 3 as an example.

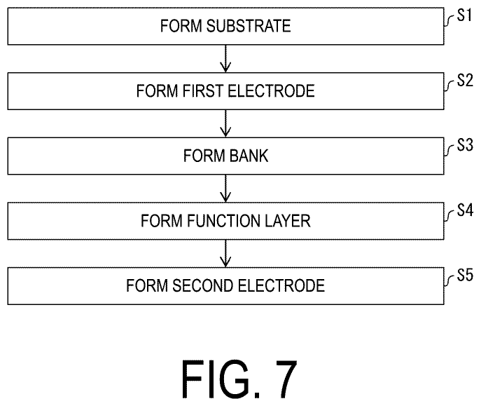

FIG. 7 is a flowchart illustrating an example of the manufacturing method for the display device 1 according to the present embodiment.

As illustrated in FIG. 7, in the present embodiment, first, the substrate 2 is formed (step S1, a substrate forming step). Subsequently, as illustrated in FIG. 3, the anode electrode 31 is formed as the first electrode (step S2, a first electrode forming step). Subsequently, the bank 32 is formed (step S3, a bank forming step). Subsequently, the function layer 33 is formed (step S4, a function layer forming step). Subsequently, for example, the cathode electrode 34 is formed as the second electrode, as illustrated in FIG. 3 (step S5, a second electrode forming step).

At step S1, the substrate 2 may be formed by forming the TFTs on the support substrate so that each of the TFTs is aligned at the position at which each of the subpixels SP of the display device 1 is to be formed.

The first electrode is formed in an island shape for each of the subpixels SP. Thus, at step S2, each of the first electrodes is formed in the island shape so as to be aligned at the position at which each of the subpixels SP of the display device 1 is to be formed. The first electrode may be formed by forming a solid-like film of the above-described conductive material over all the subpixels SP, and then patterning the film formed of the conductive material into the island shape for each of the subpixels SP by photolithography. Alternatively, the first electrode may be formed by patterning a film formed of the conductive material into the island shape for each of the subpixels SP.

On the other hand, the second electrode is a common electrode and is formed by forming a solid-like film of the conductive material commonly for all the subpixels SP at step S5.

Note that physical vapor deposition (PVD) such as a sputtering method and a vacuum vapor deposition technique, a spin coating method, or an ink-jet method can be used for the film formation of the conductive material at step S2 and step S5.

At step S3, the bank 32 can be formed in a desired shape by, for example, applying the above-described photosensitive resin to which a light absorbing agent is added, on the substrate 2 and the first electrodes, and then patterning the photosensitive resin by photolithography.

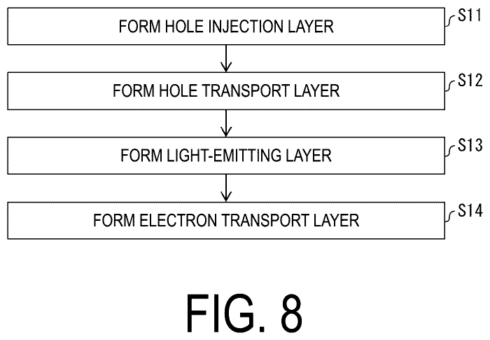

FIG. 8 is a flowchart illustrating an example of the function layer forming step (step S4).

When the first electrode is, for example, the anode electrode 31 as described above, in the function layer forming step (step S4), first, the HIL41 is formed as a first current injection layer, as illustrated in FIG. 8 (step S11, a hole injection layer forming step). Subsequently, the HTL 42 is formed as a first carrier transport layer (step S12, a hole transport layer forming step). Subsequently, the EML 43 of each color is formed (step S13, a light-emitting layer forming step). Subsequently, the ETL 44 is formed as a second carrier transport layer (step S14, an electron transport layer forming step).

At step S11, when the HTL 41 is formed of an organic material, the vacuum vapor deposition technique, the spin coating method, the ink-jet method, or the like is suitably used for film formation of the HTL 41. On the other hand, when the HTL 41 is formed of an inorganic material, for example, PVD such as the sputtering method and the vacuum vapor deposition technique, the spin coating method, the ink-jet method, or the like is suitably used for the film formation of the HTL 41.

For the film formation of the side HTL 42 at step S12 and the film formation of the side ETL 44 at step S14, a method similar to the method exemplified at step S11 is used. That is, when the film formation material used for the film formation of the HTL 42 and the film formation of the ETL 44 is an organic material, for example, PVD such as the sputtering method and the vacuum vapor deposition technique, the spin coating method, the ink-jet method, or the like is suitably used for formation of the organic material. Further, when the ETL 44 is formed of an organic material, for example, the vacuum vapor deposition technique, the spin coating method, the ink-jet method, or the like is suitably used for the film formation of the ETL 44.

Note that the above-described order of steps is for a case in which the first electrode is, for example, the anode electrode 31 as described above, and in a case in which the first electrode is the cathode electrode 34 as described above, the order of steps is reversed from that illustrated in FIG. 8. Further, a step of forming an electron injection layer (EIL) may be included between the step of forming the ETL 44 and the step of forming the cathode electrode 34.

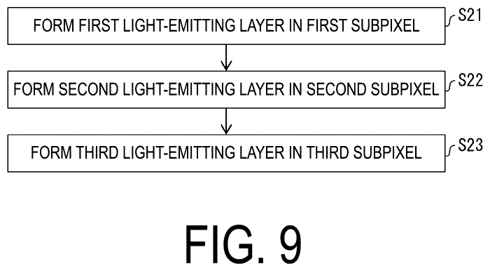

FIG. 9 is a flowchart illustrating an example of the light-emitting layer forming step (step S13).

At the light-emitting layer forming step (step S13), as illustrated in FIG. 9, first, the EML 43 as the first light-emitting layer is formed in the subpixel SP as the first subpixel (step S21, a first light-emitting layer forming step). Subsequently, the EML 43 as a second light-emitting layer is formed in the subpixel SP as the second subpixel (step S22, a second light-emitting layer forming step). Subsequently, the EML 43 as a third light-emitting layer is formed in the subpixel SP as a third subpixel (step S23, a third light-emitting layer forming step).

Note that the first light-emitting layer includes a first QD as the QD 51, a first organic ligand as the organic ligand 52, and a first inorganic ligand as the inorganic ligand 53. The second light-emitting layer includes a second QD as the QD 51, a second organic ligand as the organic ligand 52, and a second inorganic ligand as the inorganic ligand 53. The third light-emitting layer includes a third QD as the QD 51, a third organic ligand as the organic ligand 52, and a third inorganic ligand as the inorganic ligand 53.

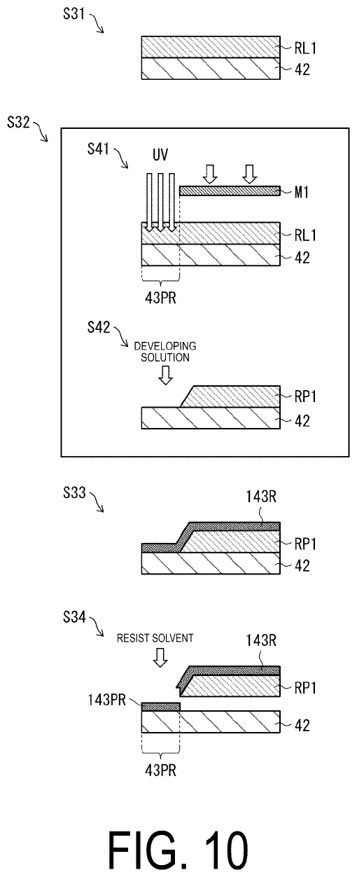

Hereinafter, the light-emitting layer forming step at step S13 will be described in more detail with reference to FIGS. 10 to 15 by using a case, as an example, in which the first light-emitting layer is the EML 43R, the second light-emitting layer is the EML 43G, and the third light-emitting layer is the EML 43B.

However, the present embodiment is not limited to the example described below. The order of formation of the EML 43R, the EML 43G, and the EML 43B is not particularly limited, and the order of formation of the EML 43R, the EML 43G, and the EML 43B can be switched. Thus, the first light-emitting layer may be the EML 43G or the EML 43B. Similarly, the second light-emitting layer may be the EML 43R or the EML 43B. Further, the third light-emitting layer may be the EML 43R or the EML 43G.

FIG. 10 is a cross-sectional view illustrating an example of a part of the first light-emitting layer forming step (step S21).

At the first light-emitting layer forming step, first, a first resist that entirely covers the plurality of subpixels SP (i.e., covers the entire pixel region DA) is applied on, for example, the HTL 42 that is an underlayer supporting the EML 43 of each color. As a result, a solid-like first resist layer RL1 is formed on the HTL 42 (step S31, a first resist layer forming step).

Note that the layer thickness of the first resist layer RL1 is not particularly limited, but may be, for example, 1 μm to 2 μm.

Subsequently, a portion of the first resist layer RL1 corresponding to a red EML planned formation region 43PR is exposed and developed. As a result, the first resist layer RL1 is patterned by removing the portion of the first resist layer RL1 corresponding to the planned formation region of the EML 43R, which serves as the first light-emitting layer (step S32, a first resist layer patterning step).

Here, the red EML planned formation region 43PR refers to a region, on the HTL 42 serving as the underlayer, in which the EML 43R is to be formed (a first light-emitting layer planned formation region).

As described above, the first resist layer patterning step (step S32) includes a first resist layer exposing step (step S41) of exposing the portion of the first resist layer RL1 corresponding to the red EML planned formation region 43PR, and a first resist layer developing step (step S42) of developing the first resist layer RL1 with a developing solution.

At the first resist layer patterning step, first, using a mask M1, the portion of the first resist layer RL1 corresponding to the red EML planned formation region 43PR is exposed (step S41, the first resist layer exposing step).

FIG. 10 illustrates a case, as an example, in which a positive-working photoresist is used as the first resist. The solubility of the positive-working photoresist with respect to the developing solution is increased by exposure to ultraviolet light (UV) or the like. Therefore, as the mask M1, a mask that exposes the portion of the first resist layer RL1 corresponding to the red EML planned formation region 43PR is used. In other words, as the mask M1, a mask is used in which an opening (optical opening) is provided so that a portion of the mask M1 corresponding to the red EML planned formation region 43PR is light-transmissive, and a portion thereof other than the portion corresponding to the red EML planned formation region 43PR has light blocking properties.

Note that the light irradiation intensity, such as the UV irradiation intensity, at step S41 may be appropriately set in accordance with the layer thickness of the first resist layer RL1 or the like, so that the portion of the first resist layer RL1 corresponding to the red EML planned formation region 43PR is removed by the development, and is not particularly limited.

Subsequently, the first resist layer RL1 is developed with the developing solution (step S42, the first resist layer developing step). As a result, the exposed portion of the first resist layer RL1 is removed, and a first resist pattern RP1 formed of the first resist layer RL1 is formed only in the portion other than the red EML planned formation region 43PR on the HTL 42.

As the developing solution, for example, an alkaline aqueous developing solution (alkaline aqueous solution) such as a tetramethylammonium hydroxide (TMAH) aqueous solution is used.

The concentration of the developing solution is not particularly limited, and may be appropriately set in accordance with the layer thickness of the first resist layer RL1, the type of the developing solution, and the like, so that the portion of the first resist layer RL1 corresponding to the red EML planned formation region 43PR is removed by the development, and is not particularly limited.

Note that in FIG. 10, as described above, the case in which the positive-working photoresist is used for the first resist layer RL1 is illustrated as an example. However, the present embodiment is not limited to this example, and a negative-working photoresist may be used instead of the positive-working photoresist. However, the solubility of the negative-working photoresist with respect to the developing solution is reduced by exposure. Thus, in this case, as the mask M1 used for the exposure of the first resist layer RL1, a mask that exposes the portion of the first resist layer RL1 other than the red EML planned formation region 43PR may be used.

In this manner, by exposing and developing a portion, of the first resist layer RL1, corresponding to the first light-emitting layer planned formation region, the first resist layer RL1 can be patterned by removing the portion of the first resist layer RL1 corresponding to the first light-emitting layer planned formation region.

After the first resist layer patterning step, subsequently, a red QD containing layer 143R as a solid-like first QD containing layer is formed so as to entirely cover the plurality of subpixels SP (i.e., cover the entire pixel region DA) (step S33, a first QD containing layer forming step). The red QD containing layer 143R includes the QD 51R as the first QD, and at least the organic ligand 52R of the organic ligand 52R as the first organic ligand and the inorganic ligand 53R as the first inorganic ligand.

Subsequently, the first resist pattern RP1 formed of the first resist layer RL1 is peeled off by a resist solvent. As a result, the red QD containing layer 143R on the first resist pattern RP1 is lifted off to remove the red QD containing layer 143R other than the red EML planned formation region 43PR (step S34, a first QD containing layer patterning step).

By performing the above-described steps S31 to S34, a red QD containing layer pattern 143PR, as a first QD containing layer pattern, formed of the red QD containing layer 143R is formed in the red EML planned formation region 43PR.

As the resist solvent, for example, a known resist solvent such as propylene glycol monomethyl ether acetate (PGMEA) can be used.

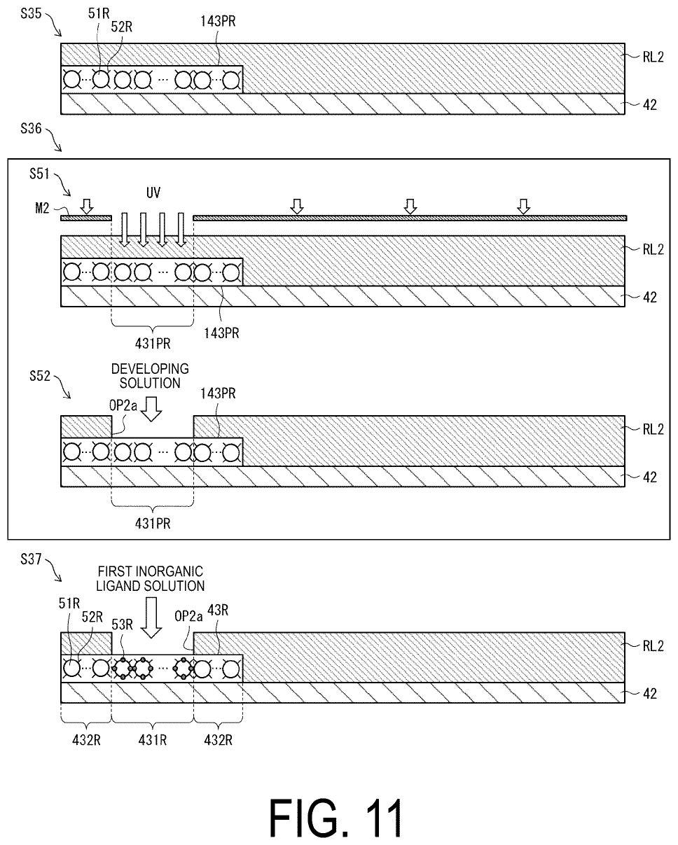

FIG. 11 is a partially enlarged cross-sectional view schematically illustrating steps of the first light-emitting layer forming step (step S21) subsequent to steps illustrated in FIG. 10. Note that in FIG. 11, the numbers of the QDs 51R and the ligands are reduced for convenience of illustration.

After the first QD containing layer patterning step, in the present embodiment, as illustrated in FIG. 11, first, a second resist that entirely covers the plurality of subpixels SP (i.e., covers the entire pixel region DA) is applied on the HTL 42 serving as the underlayer, so as to cover the red QD containing layer pattern 143PR. As a result, a solid-like second resist layer RL2 is formed on the HTL 42 on which the red QD containing layer pattern 143PR is formed (step S35, a second resist layer forming step).

Note that the layer thickness of the second resist layer RL2 is not particularly limited, but may be, for example, 1 μm to 2 μm similarly to the layer thickness of the first resist layer RL1.

Subsequently, a portion of the second resist layer RL2 corresponding to a first region planned formation region 431PR is exposed and developed. As a result, an opening OP2a (first opening) is formed in the second resist layer RL2 (step S36, a second resist layer first patterning step). The opening OP2a exposes the first region planned formation region 431PR in the red QD containing layer pattern 143PR (i.e., the patterned red QD containing layer 143R). Here, the first region planned formation region 431PR refers to a region in which the first region 431R is finally formed in the EML 43R serving as the first light-emitting layer.

As described above, the second resist layer first patterning step (step S36) includes a second resist layer first exposing step (step S51) of exposing a portion of the second resist layer RL2 corresponding to the first region planned formation region 431PR, and a second resist layer first developing step (step S52) of developing the second resist layer RL2 with a developing solution.

At the second resist layer first patterning step, first, using a mask M2, a portion of the second resist layer RL2 corresponding to the first region planned formation region 431PR is exposed (step S51, the second resist layer first exposing step).

FIG. 11 illustrates a case, as an example, in which a positive-working photoresist is used as the second resist. Therefore, as the mask M2, a mask that exposes the portion of the second resist layer RL2 corresponding to the first region planned formation region 431PR is used. In other words, as the mask M2, a mask is used in which an opening (optical opening) is provided so that a portion of the mask M2 corresponding to the first region planned formation region 431PR is light-transmissive, and a portion thereof other than the portion corresponding to the first region planned formation region 431PR has light blocking properties.

Note that the light irradiation intensity, such as the UV irradiation intensity, at step S51 may be appropriately set in accordance with the layer thickness of the second resist layer RL2 or the like, so that the portion of the second resist layer RL2 corresponding to the first region planned formation region 431PR is removed by the development, and is not particularly limited.

Subsequently, the second resist layer RL2 is developed with the developing solution (step S52, the second resist layer first developing step). As a result, the exposed portion of the second resist layer RL2 is removed, and the above-described opening OP2a is formed in the portion of the second resist layer RL2 corresponding to the first region planned formation region 431PR.

As the developing solution, for example, the developing solution exemplified above can be used. The concentration of the developing solution is also not particularly limited, and may be appropriately set in accordance with the layer thickness of the resist layer (the second resist layer RL2 at this step S52), the type of developing solution, and the like.

Note that FIG. 11 illustrates a case, as an example, in which the positive-working photoresist is used for the second resist layer RL2 in the same manner as with the first resist layer RL1. However, also for the second resist layer RL2, a negative-working photoresist may be used instead of the positive-working photoresist. In this case, as the mask M2, a mask that exposes a portion of the second resist layer RL2 other than the portion corresponding to the first region planned formation region 431PR may be used.

Note that, also at steps described below, the negative-working photoresist may be used as the resist layer, and the layer thickness of the resist layer, the exposure intensity, and the developing solution will be the same as those described above, and thus the description thereof will be omitted below.

In this manner, by exposing and developing the portion of the second resist layer RL2 corresponding to the first region planned formation region 431PR to pattern the second resist layer RL2, only the first region planned formation region 431PR of the red QD containing layer pattern 143PR can be exposed.

Therefore, subsequent to the second resist layer first patterning step, subsequently, a first inorganic ligand solution containing the inorganic ligand 53R as the first inorganic ligand is applied to the first region planned formation region 431PR exposed from the opening OP2a in the red QD containing layer pattern 143PR. As a result, the inorganic ligands 53R are supplied to the first region planned formation region 431PR (step S37, a first inorganic ligand supplying step).

By supplying the inorganic ligands 53R to the first region planned formation region 431PR in this manner, the number of the inorganic ligands 53R contained per unit volume in the first region planned formation region 431PR becomes greater than the number of the inorganic ligands 53R contained per unit volume in a region other than the first region planned formation region 431PR. In the present embodiment, a region of the red QD containing layer pattern 143PR other than the first region planned formation region 431PR is the second region 432R of the EML 43R.

At least some of the inorganic ligands 53R contained in the first inorganic ligand solution supplied to the first region planned formation region 431PR are coordinated to the QD 51R in the first region planned formation region 431PR.

The first inorganic ligand solution contains the inorganic ligands 53R and a first solvent for dissolving or dispersing the inorganic ligands 53R. The EML 43R is formed by removing and drying the solvent contained in the first inorganic ligand solution applied to the first region planned formation region 431PR.

As the first solvent, a polar solvent, other than water, that is liquid at room temperature can be used. Examples of the first solvent include non-aqueous polar solvents such as dimethyl sulfoxide (DMSO), and amphoteric solvents such as methanol and ethanol.

The concentration of the inorganic ligands 53R in the first inorganic ligand solution and the time taken to supply the first inorganic ligand solution are not particularly limited, and may be appropriately set so that the ratio of the inorganic ligands 53R to the total number of the organic ligands 52R and the inorganic ligand 53R in the first region 431R is the desired ratio described above.

Further, the removal temperature (in other words, the drying temperature) and the drying time of the first solvent are not particularly limited, and may be appropriately set so that the first solvent is removed.

As a result, the EML 43R including the first region 431R and the second region 432R is formed.

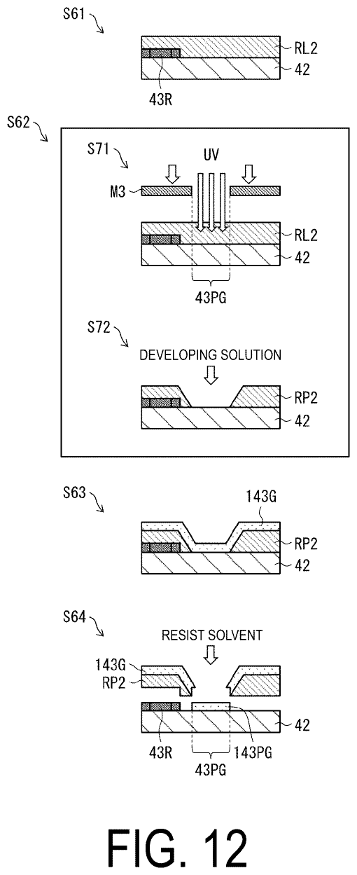

FIG. 12 is a cross-sectional view illustrating an example of a part of the second light-emitting layer forming step (step S22).

At the second light-emitting layer forming step according to the present embodiment, the second resist layer RL2 used for forming the first region 431R in the EML 43R is not removed and is used as it is for forming the EML 43G as the second light-emitting layer.

Thus, in the second light-emitting layer forming step, as illustrated in FIG. 12, subsequent to the first inorganic ligand supplying step (step S37), first, the second resist is re-applied into the opening OP2a to refill the opening OP2a with the second resist (step S61, a second resist re-applying step). As a result, the solid-like second resist layer RL2 covering the EML 43R is formed on the HTL 42.

By refilling the opening OP2a with the second resist in this manner, the second resist layer RL2 used for forming the first region 431R in the EML 43R can be used. Thus, it is not necessary to peel off the second resist layer RL2 used for forming the first region 431R subsequent to the formation of the first region 431R, or to form a resist layer from scratch after peeling off the second resist layer RL2 in order to form the EML 43G. Therefore, as compared with such a case, the number of times of applying and peeling off the resist can be reduced.

After the second resist re-applying step (step S61), a portion of the second resist layer RL2 corresponding to a green EML planned formation region 43PG is exposed and developed. As a result, the second resist layer RL2 is patterned by removing the portion of the second resist layer RL2 corresponding to the planned formation region of the EML 43G, which serves as the second light-emitting layer (step S62, a second resist layer second patterning step).

Here, the green EML planned formation region 43PG refers to a region, on the HTL 42 serving as the underlayer, in which the EML 43G is to be formed (a second light-emitting layer planned formation region).

As described above, the second resist layer second patterning step (step S62) includes a second resist layer second exposing step (step S71) of exposing the portion of the second resist layer RL2 corresponding to the green EML planned formation region 43PG, and a second resist layer second developing step (step S72) of developing the second resist layer RL2 with a developing solution.

At the second resist layer second patterning step, first, the second resist layer RL2 is exposed using a mask M3 that exposes the portion of the second resist layer RL2 corresponding to the green EML planned formation region 43PG (step S71, the second resist layer second exposing step). As the mask M3, a mask is used in which an opening (optical opening) is provided so that a portion of the mask M3 corresponding to the green EML planned formation region 43PG is light-transmissive, and a portion thereof other than the portion corresponding to the green EML planned formation region 43PG has light blocking properties.

Subsequently, the second resist layer RL2 is developed with the developing solution (step S72, the second resist layer second developing step). As a result, the exposed portion of the second resist layer RL2 is removed, and a second resist pattern RP2 formed of the second resist layer RL2 is formed only in the portion other than the green EML planned formation region 43PG on the HTL 42.

After the second resist layer second patterning step, subsequently, a solid-like green QD containing layer 143G as a second QD containing layer is formed so as to entirely cover the plurality of subpixels SP (i.e., cover the entire pixel region DA) (step S63, a second QD containing layer forming step). The green QD-containing layer 143G includes the QD 51G as the second QD, and at least the organic ligand 52G of the organic ligand 52G as the second organic ligand and the inorganic ligand 53G as the second inorganic ligand.

Subsequently, the second resist pattern RP2 formed of the second resist layer RL2 is peeled off, for example, by the above-described resist solvent. As a result, the green QD containing layer 143G on the second resist pattern RP2 is lifted off to remove the green QD containing layer 143G other than the green EML planned formation region 43PG (step S64, a second QD containing layer patterning step).

By performing the above-described steps S61 to S64, a green QD containing layer pattern 143PG, as a second QD containing layer pattern, formed of the green QD containing layer 143G is formed in the green EML planned formation region 43PG.

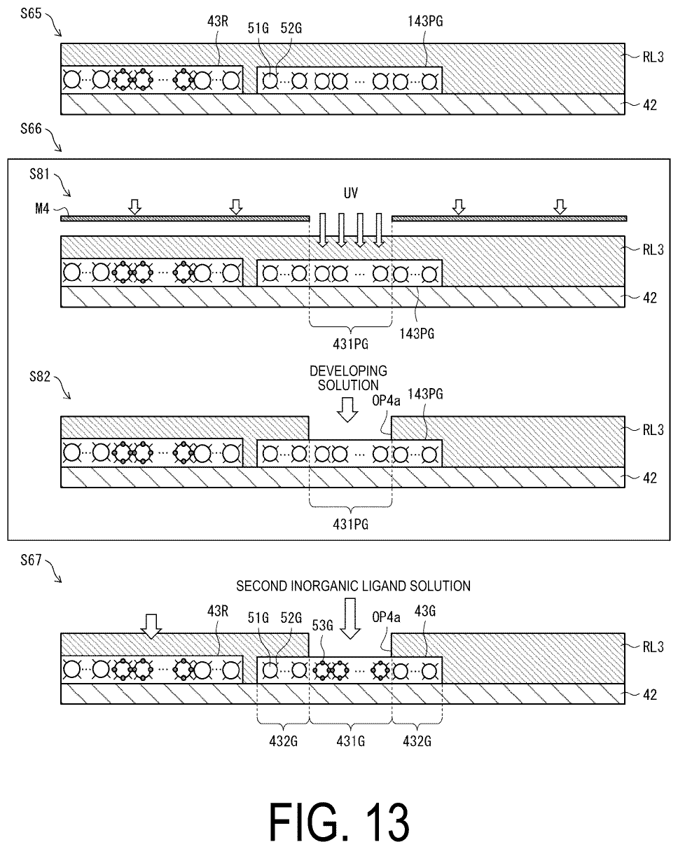

FIG. 13 is a partially enlarged cross-sectional view schematically illustrating steps of the second light-emitting layer forming step (step S22) subsequent to steps illustrated in FIG. 12. Note that in FIG. 13, the numbers of the QDs 51R, the QDs 51G, and the ligands are reduced for convenience of illustration.

After the second QD containing layer patterning step, in the present embodiment, as illustrated in FIG. 13, first, a third resist that entirely covers the plurality of subpixels SP (i.e., covers the entire pixel region DA) is applied on the HTL 42 serving as the underlayer, so as to cover the EML 43R and the green QD containing layer pattern 143PG. As a result, a solid-like third resist layer RL3 is formed on the HTL 42 on which the EML 43R and the green QD containing layer pattern 143PG are formed (step S65, a third resist layer forming step).

Subsequently, a portion of the third resist layer RL3 corresponding to a first region planned formation region 431PG is exposed and developed. As a result, an opening OP4a (second opening) is formed in the third resist layer RL3 (step S66, a third resist layer first patterning step). The opening OP4a exposes the first region planned formation region 431PG in the green QD containing layer pattern 143PG (i.e., the patterned green QD containing layer 143G). Here, the first region planned formation region 431PG refers to a region in which the first region 431G is finally formed in the EML 43G serving as the second light-emitting layer.

As described above, the third resist layer first patterning step (step S66) includes a third resist layer first exposing step (step S81) of exposing a portion of the third resist layer RL3 corresponding to the first region planned formation region 431PG, and a third resist layer first developing step (step S82) of developing the third resist layer RL3 with a developing solution.

At the third resist layer first patterning step, first, using a mask M4, the portion of the third resist layer RL3 corresponding to the first region planned formation region 431PG is exposed (step S81, the third resist layer first exposing step).

FIG. 13 illustrates a case, as an example, in which a positive-working photoresist is used as the third resist. Therefore, as the mask M4, a mask that exposes the portion of the third resist layer RL3 corresponding to the first region planned formation region 431PG is used. In other words, as the mask M4, a mask is used in which an opening (optical opening) is provided so that a portion of the mask M4 corresponding to the first region planned formation region 431PG is light-transmissive, and a portion thereof other than the portion corresponding to the first region planned formation region 431PG has light blocking properties.

Subsequently, the third resist layer RL3 is developed with the developing solution (step S82, the third resist layer first developing step). As a result, the exposed portion of the third resist layer RL3 is removed, and the above-described opening OP4a is formed in the portion of the third resist layer RL3 corresponding to the first region planned formation region 431PG.

In this manner, by exposing and developing the portion of the third resist layer RL3 corresponding to the first region planned formation region 431PG to pattern the third resist layer RL3, only the first region planned formation region 431PG of the green QD containing layer pattern 143PG can be exposed.

Thus, subsequent to the third resist layer first patterning step, subsequently, a second inorganic ligand solution containing the inorganic ligands 53G as the second inorganic ligands is applied to the first region planned formation region 431PG exposed from the opening OP4a in the green QD containing layer pattern 143PG. As a result, the inorganic ligands 53G are supplied to the first region planned formation region 431PG (step S67, a second inorganic ligand supplying step).

By supplying the inorganic ligands 53G to the first region planned formation region 431PG in this manner, the number of the inorganic ligands 53G contained per unit volume in the first region planned formation region 431PG becomes greater than the number of the inorganic ligands 53G contained per unit volume in a region other than the first region planned formation region 431PG. In the present embodiment, a region of the green QD containing layer pattern 143PG other than the first region planned formation region 431PG is the second region 432G of the EML 43G.

At least some of the inorganic ligands 53G contained in the second inorganic ligand solution supplied to the first region planned formation region 431PG are coordinated to the QD 51G in the first region planned formation region 431PG.

The second inorganic ligand solution contains the inorganic ligands 53G and a second solvent for dissolving or dispersing the inorganic ligands 53G. The EML 43G is formed by removing and drying the solvent contained in the second inorganic ligand solution applied to the first region planned formation region 431PG.

Examples of the second solvent include the same solvents as those exemplified as the first solvent. The concentration of the inorganic ligands 53G in the second inorganic ligand solution and the time taken to supply the second inorganic ligand solution are not particularly limited, and may be appropriately set so that the ratio of the inorganic ligands 53G to the total number of the organic ligands 52G and the inorganic ligand 53G in the first region 431G is the desired ratio described above.

Further, the removal temperature (in other words, the drying temperature) and the drying time of the second solvent are not particularly limited, and may be appropriately set so that the second solvent is removed.

As a result, the EML 43G including the first region 431G and the second region 432G is formed.

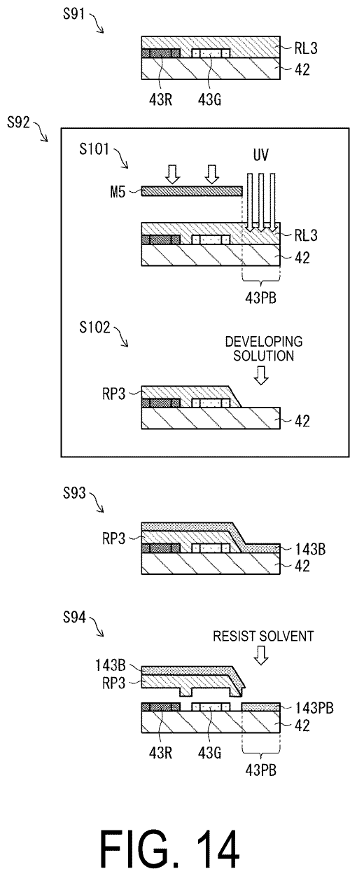

FIG. 14 is a cross-sectional view illustrating an example of a part of the third light-emitting layer forming step (step S23).

At the third light-emitting layer forming step according to the present embodiment, the third resist layer RL3 used for forming the first region 431G in the EML 43G is not removed and is used as it is for forming the EML 43B as the third light-emitting layer.

Thus, in the third light-emitting layer forming step, as illustrated in FIG. 14, subsequent to the second inorganic ligand supplying step (step S67), first, the third resist is re-applied into the opening OP4a to refill the opening OP4a with the third resist (step S91, a third resist re-applying step). As a result, the solid-like third resist layer RL3 covering the EML 43R and the EML 43G is formed on the HTL 42.

By refilling the opening OP4a with the third resist in this manner, the third resist layer RL3 used for forming the first region 431G in the EML 43G can be used. Thus, it is not necessary to peel off the third resist layer RL3 used for forming the first region 431G subsequent to the formation of the first region 431G, or to form a resist layer from scratch after peeling off the third resist layer RL3 in order to form the EML 43B. Therefore, as compared with such a case, the number of times of applying and peeling off the resist can be reduced.

After the third resist re-applying step (step S91), a portion of the third resist layer RL3 corresponding to a blue EML planned formation region 43PB is exposed and developed. As a result, the third resist layer RL3 is patterned by removing the portion of the third resist layer RL3 corresponding to the planned formation region of the EML 43B, which serves as the third light-emitting layer (step S92, a third resist layer second patterning step).

Here, the blue EML planned formation region 43PB refers to a region, on the HTL 42 serving as the underlayer, in which the EML 43B is to be formed (a third light-emitting layer planned formation region).

As described above, the third resist layer second patterning step (step S92) includes a third resist layer second exposing step (step S101) of exposing the portion of the third resist layer RL3 corresponding to the blue EML planned formation region 43PB, and a third resist layer second developing step (step S102) of developing the third resist layer RL3 with a developing solution.

At the third resist layer second patterning step, first, the third resist layer RL3 is exposed using a mask M5 that exposes the portion of the third resist layer RL3 corresponding to the blue EML planned formation region 43PB (step S101, the third resist layer third exposing step). As the mask M5, a mask is used in which an opening (optical opening) is provided so that a portion of the mask M5 corresponding to the blue EML planned formation region 43PB is light-transmissive, and a portion thereof other than the portion corresponding to the blue EML planned formation region 43PB has light blocking properties.

Subsequently, the third resist layer RL3 is developed with the developing solution (step S102, the third resist layer second developing step). As a result, the exposed portion of the third resist layer RL3 is removed, and a third resist pattern RP3 formed of the third resist layer RL3 is formed only in the portion other than the blue EML planned formation region 43PB on the HTL 42.

After the third resist layer second patterning step, subsequently, a solid-like blue QD containing layer 143B as a third QD containing layer is formed so as to entirely cover the plurality of subpixels SP (i.e., cover the entire pixel region DA) (step S93, a third QD containing layer forming step). The blue QD-containing layer 143B includes the QD 51B as the third QD, and at least the organic ligand 52B of the organic ligand 52B as the third organic ligand and the inorganic ligand 53B as the third inorganic ligand.

Subsequently, the third resist pattern RP3 formed of the third resist layer RL3 is peeled off, for example, by the above-described resist solvent. As a result, the blue QD containing layer 143B on the third resist pattern RP3 is lifted off to remove the blue QD containing layer 143B other than the blue EML planned formation region 43PB (step S94, a third QD containing layer patterning step).

By performing the above-described steps S91 to S94, a blue QD containing layer pattern 143PB, as a third QD containing layer pattern, formed of the blue QD containing layer 143B is formed in the blue EML planned formation region 43PB.

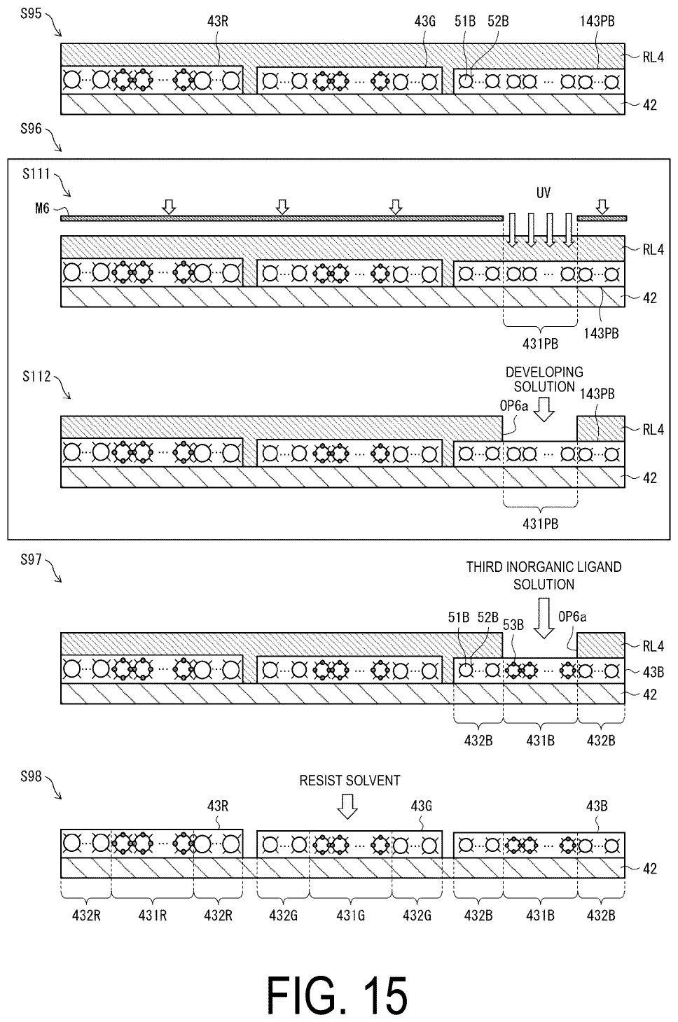

FIG. 15 is a partially enlarged cross-sectional view schematically illustrating steps of the third light-emitting layer forming step (step S23) subsequent to steps illustrated in FIG. 14. Note that in FIG. 15, the numbers of the QDs 51R, the QDs 51G, the QDs 51B, and the ligands are reduced for convenience of illustration.

After the third QD containing layer patterning step, in the present embodiment, as illustrated in FIG. 15, first, a fourth resist that entirely covers the plurality of subpixels SP (i.e., covers the entire pixel region DA) is applied on the HTL 42 serving as the underlayer, so as to cover the EML 43R, the EML 43G, and the blue QD containing layer pattern 143PB. As a result, a solid-like fourth resist layer RL4 is formed on the HTL 42 on which the EML 43R, the EML 43G, and the blue QD containing layer pattern 143PB are formed (step S95, a fourth resist layer forming step).

Subsequently, a portion of the fourth resist layer RL4 corresponding to a first region planned formation region 431PB is exposed and developed. As a result, an opening OP6a (third opening) is formed in the fourth resist layer RL4 (step S96, a fourth resist layer first patterning step). The opening OP4a exposes the first region planned formation region 431PB in the blue QD containing layer pattern 143PB (i.e., the patterned blue QD containing layer 143B). Here, the first region planned formation region 431PB refers to a region in which the first region 431B is finally formed in the EML 43B serving as the third light-emitting layer.

As described above, the fourth resist layer first patterning step (step S96) includes a fourth resist layer first exposing step (step S111) of exposing the portion of the fourth resist layer RL4 corresponding to the first region planned formation region 431PB, and a fourth resist layer first developing step (step S112) of developing the fourth resist layer RL4 with a developing solution.

At the fourth resist layer first patterning step, first, using a mask M6, the portion of the fourth resist layer RL4 corresponding to the first region planned formation region 431PB is exposed (step S111, the fourth resist layer first exposing step).

FIG. 15 illustrates a case, as an example, in which a positive-working photoresist is used as the fourth resist. Therefore, as the mask M6, a mask that exposes the portion of the fourth resist layer RL4 corresponding to the first region planned formation region 431PB is used. In other words, as the mask M6, a mask is used in which an opening (optical opening) is provided so that a portion of the mask M6 corresponding to the first region planned formation region 431PB is light-transmissive, and a portion thereof other than the portion corresponding to the first region planned formation region 431PB has light blocking properties.

Subsequently, the fourth resist layer RL4 is developed with the developing solution (step S112, the fourth resist layer first developing step). As a result, the exposed portion of the fourth resist layer RL4 is removed, and the above-described opening OP6a is formed in the portion of the fourth resist layer RL4 corresponding to the first region planned formation region 431PB.

In this manner, by exposing and developing the portion of the fourth resist layer RL4 corresponding to the first region planned formation region 431PB to pattern the fourth resist layer RL4, only the first region planned formation region 431PB of the blue QD containing layer pattern 143PB can be exposed.

Thus, subsequent to the fourth resist layer first patterning step, subsequently, a third inorganic ligand solution containing the inorganic ligands 53B as the third inorganic ligands is applied to the first region planned formation region 431PB exposed from the opening OP6a in the blue QD containing layer pattern 143PB. As a result, the inorganic ligands 53B are supplied to the first region planned formation region 431PB (step S97, a third inorganic ligand supplying step).

By supplying the inorganic ligands 53B to the first region planned formation region 431PB in this manner, the number of the inorganic ligands 53B contained per unit volume in the first region planned formation region 431PB becomes greater than the number of the inorganic ligands 53B contained per unit volume in a region other than the first region planned formation region 431PB. In the present embodiment, a region of the blue QD containing layer pattern 143PB other than the first region planned formation region 431PB is the second region 432B of the EML 43B.

At least some of the inorganic ligands 53B contained in the third inorganic ligand solution supplied to the first region planned formation region 431PB are coordinated to the QD 51B in the first region planned formation region 431PB.

The third inorganic ligand solution contains the inorganic ligands 53B and a third solvent for dissolving or dispersing the inorganic ligands 53B. The EML 43B is formed by removing and drying the solvent contained in the third inorganic ligand solution applied to the first region planned formation region 431PB.

Examples of the third solvent include the same solvents as those exemplified as the first solvent. The concentration of the inorganic ligands 53B in the third inorganic ligand solution and the time taken to supply the third inorganic ligand solution are not particularly limited, and may be appropriately set so that the ratio of the inorganic ligands 53B to the total number of the organic ligands 52B and the inorganic ligand 53B in the first region 431B is the desired ratio described above.

Further, the removal temperature (in other words, the drying temperature) and the drying time of the third solvent are not particularly limited, and may be appropriately set so that the third solvent is removed.

As a result, the EML 43B including the first region 431B and the second region 432B is formed.

Subsequently, by dissolving the fourth resist layer RL4, for example, by the above-described resist solvent, the fourth resist layer RL4 is removed (step S98, a fourth resist layer removing step). As a result, on the HTL 42, the plurality of island-shaped EMLs 43 are formed that include the EML 43R including the first region 431R and the second region 432R, the EML 43G including the first region 431G and the second region 432G, and the EML 43B including the first region 431B and the second region 432B.

According to the present embodiment, as described above, subsequent to the formation of the first region 431 in the first light-emitting layer and subsequent to the formation of the first region 431 in the second light-emitting layer, without removing the resist layer used for the formation of the first regions 431, the resist is re-applied only to the opening provided in the resist layer in order to refill the resist layer. Thus, as described above, it is possible to reduce the number of times of applying and peeling off the resist and to protect the QDs 51 of the subpixel peripheral portion, which still remains covered with the resist layer. Note that although the number of times of applying and peeling off the resist increases in the subpixel central portion that forms the first region 431, the QDs 51 in the first region 431 are protected by the inorganic ligands 53, and thus are unlikely to deteriorate.

Further, according to the present embodiment, as described above, since the first region 431 is formed for each of the subpixels SP of each color, it is possible to use the different inorganic ligands 53 in accordance with the luminescent color of the subpixel SP.

According to the present embodiment, by performing steps illustrated in FIGS. 7 to 15, the display device 1 according to the present embodiment can be manufactured. Note that, in the manufacturing method for the display device 1 according to the present embodiment, a step of forming a sealing layer or the like in a layer above the light-emitting element layer 3 may further be included subsequent to the second electrode forming step (step S5) illustrated in FIG. 7.

As described above, the manufacturing method for the display device 1 according to the present embodiment includes the first electrode forming step of forming the first electrode, the function layer forming step of forming the function layer 33, and the second electrode forming step of forming the second electrode. Further, the function layer forming step includes the light-emitting layer forming step of forming the EML 43. Then, in the light-emitting layer forming step, the EML 43 having the following configuration is formed as the light-emitting layer for each of the subpixels SP. The EML 43 formed in the light-emitting layer forming step includes (1) the first region 431 including the QD 51, the organic ligand 52, and the inorganic ligand 53, and (2) the second region 432 including the QD 51, and at least the organic ligand 52 of the organic ligand 52 and the inorganic ligand 53. In the second region 432, the number of the inorganic ligands 53 contained per unit volume is less than the number of the inorganic ligands 53 contained per unit volume in the first region 431. Then, the first region 431 includes the central portion of the EML 43 of each of the subpixels SP. The second region 432 includes at least the end portions, of the EML 43 of each of the subpixels SP, adjacent to the other subpixels SP.

As a result, according to the present embodiment, it is possible to achieve both the improvement in the light emission efficiency by the inorganic ligand 53 and the suppression of the light emission caused by the leakage current from the adjacent subpixel SP, and further, it is possible to narrow the interval between the subpixels SP and to provide the manufacturing method for the display device 1 having excellent display quality.

### Modified Example

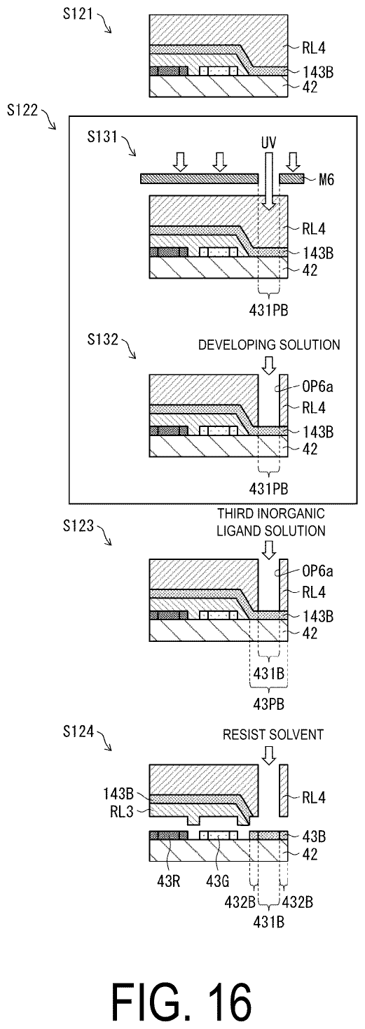

However, the manufacturing method for the display device 1 according to the present embodiment is not limited to the above-described method. FIG. 16 is a cross-sectional view illustrating another example of a part of the third light-emitting layer forming step (step S23) according to the present embodiment. FIG. 16 is a cross-sectional view illustrating steps subsequent to step S93 (third QD containing layer forming step) illustrated in FIG. 14.

In the present modified example, subsequent to step S93 (third QD containing layer forming step) illustrated in FIG. 14, the fourth resist is applied to entirely cover the plurality of subpixels SP (i.e., cover the entire pixel region DA) so as to cover the solid-like blue QD containing layer 143B. As a result, the solid-like fourth resist layer RL4 is formed on the blue QD containing layer 143B (step S121, a fourth resist layer forming step).

Subsequently, a portion of the fourth resist layer RL4 corresponding to a first region planned formation region 431PB is exposed and developed. As a result, the opening OP6a (third opening), which exposes the first region planned formation region 431PB in the blue QD containing layer pattern 143B, is formed in the fourth resist layer RL4 (step S122, a fourth resist layer first patterning step).

As described above, the fourth resist layer first patterning step (step S122) includes a fourth resist layer first exposing step (step S131) of exposing the portion of the fourth resist layer RL4 corresponding to the first region planned formation region 431PB, and a fourth resist layer first developing step (step S132) of developing the fourth resist layer RL4 with a developing solution.

At the fourth resist layer first patterning step, first, using the mask M5, the portion of the fourth resist layer RL4 corresponding to the first region planned formation region 431PB is exposed (step S131, the fourth resist layer first exposing step).

Subsequently, the fourth resist layer RL4 is developed with the developing solution (step S132, the fourth resist layer first developing step). As a result, the exposed portion of the fourth resist layer RL4 is removed, and the above-described opening OP6a is formed in the portion of the fourth resist layer RL4 corresponding to the first region planned formation region 431PB.

Note that only the lower layer of the fourth resist layer RL4 is different, and in terms of the operation itself, step S122 is the same as step S96, step S131 is the same as step S111, and step S132 is the same as step S112. As a result, it is possible to expose only the first region planned formation region 431PB in the blue QD containing layer 143B.

Thus, subsequent to the fourth resist layer first patterning step, subsequently, the third inorganic ligand solution containing the inorganic ligands 53B as the third inorganic ligands is applied to the first region planned formation region 431PB exposed from the opening OP6a in the blue QD containing layer 143B. As a result, the inorganic ligands 53B are supplied to the first region planned formation region 431PB (step S123, a third inorganic ligand supplying step).

As a result, the number of the inorganic ligands 53B contained per unit volume in the first region planned formation region 431PB becomes greater than the number of the inorganic ligands 53B contained per unit volume in the region other than the first region planned formation region 431PB. Thus, also in the present modified example, the first region 431B is formed in the first region planned formation region 431PB.

Thereafter, also in the present modified example, the solvent contained in the third inorganic ligand solution applied to the first region planned formation region 431PB is removed and dried, and then, the resist layer is removed by the resist solvent.

However, in the present modified example, subsequent to step S93, the fourth resist layer forming step (step S121) corresponding to step S95 is performed without performing step S94 (third QD containing layer patterning step). Therefore, the third resist layer RL3 and the blue QD containing layer 143B that cover the EML 43R and the EML 43G remain in a region other than the blue EML planned formation region 43PB.

Therefore, in the present modified example, the fourth resist layer RL4 is removed by the resist solvent, and the blue QD containing layer 143B on the third resist layer RL3 is lifted off as a result of the third resist layer RL3 being peeled off by the resist solvent. As a result, here, the blue QD containing layer 143B in the region other than the blue EML planned formation region 43PB is removed (step S124, a third QD containing layer patterning step).

According to the present modified example, as described above, the third QD containing layer patterning step performed by peeling off the third resist layer RL3, and the fourth resist layer removing step can be performed simultaneously (i.e., at the same step). Therefore, the tact time can be shortened, and the above-described display device 1 according to the present embodiment can thus be more easily manufactured.

### Second Embodiment

The first embodiment is described above using a case, as an example, in which the number of times of applying and peeling off the resist is reduced by using the step of applying the resist on the QDs having the different luminescent colors. In other words, the first embodiment is described above using a case, as an example, in which the resist layer used for forming the first region 431 of the first light-emitting layer is used for forming the second light-emitting layer, and the resist layer used for forming the first region 431 of the second light-emitting layer is used for forming the third light-emitting layer. However, the manufacturing method for the display device 1 is not limited to this example, and the inorganic ligands 53 may be supplied after the red QD containing layer pattern 143PR, the green QD containing layer pattern 143PG, and the blue QD containing layer pattern 143PB are formed, respectively.

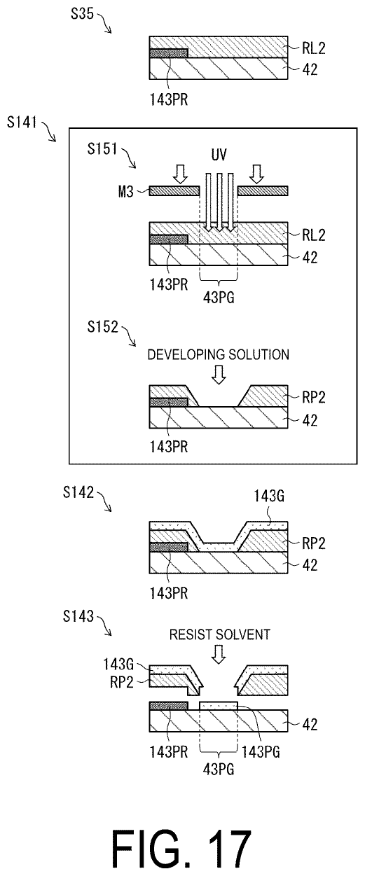

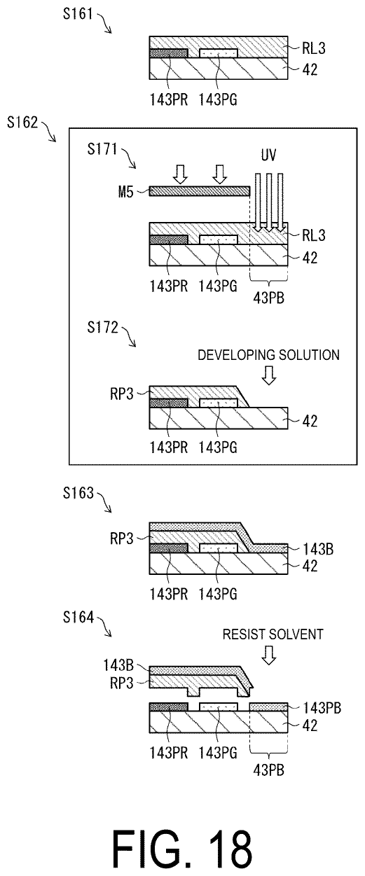

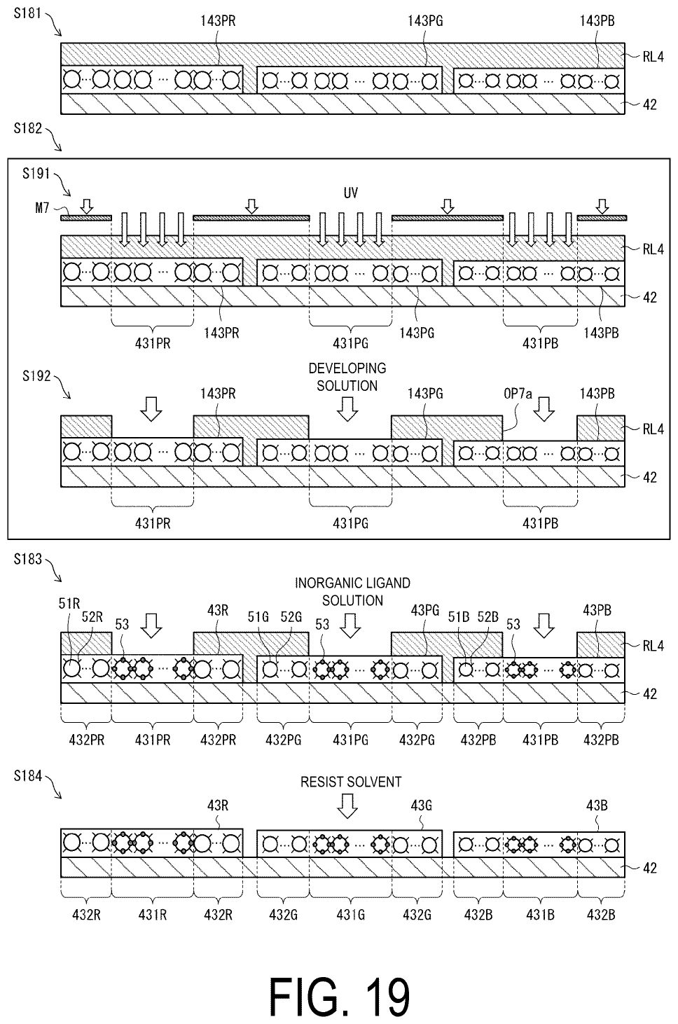

FIGS. 17 and 18 are each a cross-sectional view illustrating an example of a part of the light-emitting layer forming step (step S13) according to the present embodiment. FIG. 19 is an enlarged cross-sectional view schematically illustrating a portion of the EML 43 of each color according to an example of a part of the light-emitting layer forming step (step S13) according to the present embodiment. Note that FIG. 18 illustrates steps subsequent to steps illustrated in FIG. 17. Note that FIG. 19 illustrates steps subsequent to the steps illustrated in FIG. 18.

In the present embodiment, first, step S31 (first resist layer forming step) to step S34 (first QD containing layer patterning step) illustrated in FIG. 10 are performed. As a result, as indicated by S34 in FIG. 10, the red QD containing layer pattern 143PR formed of the red QD containing layer 143R is formed in the red EML planned formation region 43PR.

Subsequently, as indicated by S35 in FIGS. 11 and 17, the second resist is applied to entirely cover the plurality of subpixels SP (i.e., cover the entire pixel region DA). As a result, the solid-like second resist layer RL2 is formed on the HTL 42 on which the red QD containing layer pattern 143PR is formed (step S35, the second resist layer forming step). The steps up to this point are the same as those of the first embodiment.

In the present embodiment, subsequent to the second resist layer forming step (step S34), subsequently, as illustrated in FIG. 17, the portion of the second resist layer RL2 corresponding to the green EML planned formation region 43PG is exposed and developed. As a result, the second resist layer RL2 is patterned by removing the portion of the second resist layer RL2 corresponding to the green EML planned formation region 43PG (step S141, a second resist layer patterning step).

As described above, the second resist layer patterning step (step S141) includes a second resist layer exposing step (step S151) of exposing the portion of the second resist layer RL2 corresponding to the green EML planned formation region 43PG, and a second resist layer developing step (step S152) of developing the second resist layer RL2 with a developing solution.

Note that step S141 is the same as step S62 illustrated in FIG. 12, except that the red QD containing layer pattern 143PR, in which the first region 431R and the second region 432R are not provided, is provided instead of the EML 43R. Therefore, in terms of the operation itself, step S141 is the same as step S62, step S151 is the same as step S71, and step S152 is the same as step S72.

Thus, in the second resist layer exposing step (step S151), the second resist layer RL2 is exposed using the mask M3 that exposes the portion of the second resist layer RL2 corresponding to the green EML planned formation region 43PG. Thereafter, in the second resist layer developing step (step S152), the second resist layer RL2 is developed with the developing solution.

Subsequently, the solid-like green QD containing layer 143G is formed so as to entirely cover the plurality of subpixels SP (i.e., cover the entire pixel region DA) (step S142, a second QD containing layer forming step).

Subsequently, the second resist pattern RP2 formed of the second resist layer RL2 is peeled off by the resist solvent. As a result, the green QD containing layer 143G on the second resist pattern RP2 is lifted off to remove the green QD containing layer 143G other than the green EML planned formation region 43PG (step S143, a second QD containing layer patterning step). As a result, the green QD containing layer pattern 143PG formed of the green QD containing layer 143G is formed in the green EML planned formation region 43PG.

Note that, here also, step S142 is the same as step S63 and step S143 is the same as step S64, except that the red QD containing layer pattern 143PR is provided instead of the EML 43R.

Subsequently, as illustrated in FIG. 18, the solid-like third resist layer RL3, which entirely covers the plurality of subpixels SP (i.e., covers the entire pixel region DA), is formed on the HTL 42 on which the red QD containing layer pattern 143PR and the green QD containing layer pattern 143PG are formed (step S161, a third resist layer forming step).

Subsequently, the portion of the third resist layer RL3 corresponding to the blue EML planned formation region 43PB is exposed and developed. As a result, the third resist layer RL3 is patterned by removing the third resist layer RL3 of the blue EML planned formation region 43PB (step S162, a third resist layer patterning step).

As described above, the third resist layer patterning step (step S162) includes a third resist layer exposing step (step S171) of exposing the portion of the third resist layer RL3 corresponding to the blue EML planned formation region 43PB, and a third resist layer developing step (step S172) of developing the third resist layer RL3 with a developing solution.

Note that step S162 is the same as step S92 illustrated in FIG. 14, except that the red QD containing layer pattern 143PR and the green QD containing layer pattern 143PG, in which the first region 431 and the second region 432 are not provided, are provided instead of the EML 43R and the EML 43G. Therefore, in terms of the operation itself, step S162 is the same as step S92, step S171 is the same as step S101, and step S172 is the same as step S102.

Therefore, in the third resist layer exposing step (Step S171), the third resist layer RL3 is exposed using the mask M5 that exposes the portion of the third resist layer RL3 corresponding to the blue EML planned formation region 43PB. Thereafter, in the third resist layer developing step (step S172), the third resist layer RL3 is developed with the developing solution.

Subsequently, the solid-like blue QD containing layer 143B is formed so as to entirely cover the plurality of subpixels SP (i.e., cover the entire pixel region DA) (step S163, a third QD containing layer forming step).

Subsequently, the third resist pattern RP3 formed of the third resist layer RL3 is peeled off by the resist solvent. As a result, the blue QD containing layer 143B on the third resist pattern RP3 is lifted off to remove the blue QD containing layer 143B other than the blue EML planned formation region 43PB (step S164, a third QD containing layer patterning step).

Note that, here also, step S163 is the same as step S93 and step S164 is the same as step S94, except that the red QD containing layer pattern 143PR and the green QD containing layer pattern 143PG are provided instead of the EML 43R and the EML 43G.

Subsequently, as illustrated in FIG. 19, on the HTL 42 on which the red QD containing layer pattern 143PR, the green QD containing layer pattern 143PG, and the blue QD containing layer pattern 143PB are formed, the solid-like fourth resist layer RL4 is formed to entirely cover the plurality of subpixels SP (i.e., cover the entire pixel region DA) (step S181, a fourth resist layer forming step).

Subsequently, portions of the fourth resist layer RL4 respectively corresponding to the first region planned formation region 431PR, the first region planned formation region 431PG, and the first region planned formation region 431PB are exposed and developed. As a result, openings OP7a that expose the first region planned formation region 431PR, the first region planned formation region 431PG, and the first region planned formation region 431PB, respectively, are formed in the fourth resist layer RL4 (step S182, a fourth resist layer patterning step).

As described above, the fourth resist layer patterning step (step S182) includes a fourth resist layer exposing step (step S191) of exposing the portions of the fourth resist layer RL4 respectively corresponding to the first region planned formation region 431PR, the first region planned formation region 431PG, and the first region planned formation region 431PB, and a fourth resist layer developing step (step S192) of developing the fourth resist layer RL4 with a developing solution.

At the fourth resist layer exposing step (step S191), a mask M7 is used to expose the portions of the fourth resist layer RL4 respectively corresponding to the first region planned formation region 431PR, the first region planned formation region 431PG, and the first region planned formation region 431PB.

At the fourth resist layer developing step (step S192), the exposed portions are developed with the developing solution and removed to form the openings OP7a on the fourth resist layer RL4. As a result, the first region planned formation region 431PR in the red QD containing layer pattern 143PR, the first region planned formation region 431PG in the green QD containing layer pattern 143PG, and the first region planned formation region 431PB in the blue QD containing layer pattern 143PB are exposed.

After the fourth resist layer patterning step, subsequently, an inorganic ligand solution containing the inorganic ligands 53 is applied to the first region planned formation region 431PR, the first region planned formation region 431PG, and the first region planned formation region 431PB exposed from the openings OP7a. As a result, the inorganic ligands 53B are supplied to each of the first region planned formation region 431PR, the first region planned formation region 431PG, and the first region planned formation region 431PB (step S183, an inorganic ligand supplying step).

As a result, the number of the inorganic ligands 53 contained per unit volume in the first region planned formation region 431PR, the first region planned formation region 431PG, and the first region planned formation region 431PB becomes greater than the number of the inorganic ligands 53 contained per unit volume in a region other than the first region planned formation region 431PR, the first region planned formation region 431PG, and the first region planned formation region 431PB.

As a result, the first region 431R is formed in the first region planned formation region 431PR, the first region 431G is formed in the first region planned formation region 431PG, and the first region 431B is formed in the first region planned formation region 431PB. Then, a region other than the first region planned formation region 431PR in the red QD containing layer pattern 143PR becomes the second region 432R of the EML 43R. Further, a region other than the first region planned formation region 431PG in the green QD containing layer pattern 143PG becomes the second region 432G of the EML 43G. Further, a region other than the first region planned formation region 431PB in the blue QD containing layer pattern 143PB becomes the second region 432B of the EML 43B.

The above-described inorganic ligand solution contains the inorganic ligands 53 and a solvent for dissolving or dispersing the inorganic ligands 53. In other words, in the example illustrated in FIG. 19, the same inorganic ligands 53 are used as the inorganic ligands 53R, the inorganic ligands 53G, and the inorganic ligands 53B.

Note that examples of the solvent used for the inorganic ligand solution include the same solvents as those exemplified as the first solvent. The concentration of the inorganic ligands 53 in the inorganic ligand solution and the time taken to supply the inorganic ligand solution are not particularly limited, and may be appropriately set so that the ratio of the inorganic ligands 53 to the total number of the organic ligands 52 and the inorganic ligand 53 in the first region 431 is the desired ratio described above.

Thereafter, after removing and drying the solvent contained in the inorganic ligand solution applied to the first region planned formation region 431PR, the first region planned formation region 431PG, and the first region planned formation region 431PB, the fourth resist layer RL4 is removed by the resist solvent (step S184, a fourth resist layer removing step).

As a result, on the HTL 42, the plurality of island-shaped EMLs 43 are formed that include the EML 43R including the first region 431R and the second region 432R, the EML 43G including the first region 431G and the second region 432G, and the EML 43B including the first region 431B and the second region 432B.

Note that the removal temperature (in other words, the drying temperature) and the drying time of the solvent are not particularly limited, and may be appropriately set so that the solvent is removed.

As described above, when the same inorganic ligands 53 are used as the inorganic ligands 53R, the inorganic ligands 53G, and the inorganic ligands 53B, the supplies of the inorganic ligands 53 to the first region planned formation region 431PR, the first region planned formation region 431PG, and the first region planned formation region 431PB can be performed simultaneously. As a result, the number of times of applying and peeling off the resist can be reduced, the tact time can be shortened, and the display device 1 according to the present embodiment can thus be more easily manufactured.

### First Modified Example

In FIG. 19, as described above, a case is described, as an example, in which the supplies of the inorganic ligands 53 to the first region planned formation region 431PR, the first region planned formation region 431PG, and the first region planned formation region 431PB are performed simultaneously, but the present embodiment is not limited to this example.

For example, at step S182, an opening is formed only in the first region planned formation region of the first light-emitting layer in the fourth resist layer RL4, the first inorganic ligand solution containing the first inorganic ligands is supplied to the opening, and then, the opening is refilled with the fourth resist. Thereafter, an opening is formed only in the first region planned formation region of the second light-emitting layer, the second inorganic ligand solution containing the second inorganic ligands is supplied to the opening, and then, the opening is refilled with the fourth resist. Thereafter, an opening is formed only in the first region planned formation region of the third light-emitting layer, the third inorganic ligand solution containing the third inorganic ligands is supplied to the opening. Finally, the fourth resist layer RL4 is removed. The EML 43R, the EML 43G, and the EML 43B may be formed in this manner. In this case, inorganic ligand solutions of different types or having different concentrations may be used as the first inorganic ligand solution, the second inorganic ligand solution, and the third inorganic ligand solution.

In this manner, subsequent to step S164 illustrated in FIG. 18, steps similar to steps S35 to S37 illustrated in FIG. 11 may be performed, then steps similar to steps S65 to S67 illustrated in FIG. 13 may be performed, and thereafter, steps similar to steps S95 to S98 illustrated in FIG. 15 may be performed. Note that, in this case, the steps are the same as those illustrated in FIGS. 11, 13, and 15, except that the red QD containing layer pattern 143PR, the green QD containing layer pattern 143PG, and the blue QD containing layer pattern 143PB are formed in advance as the QD containing layer patterns on the HTL 42. Thus, the illustration thereof is omitted in the present modified example.

### Second Modified Example

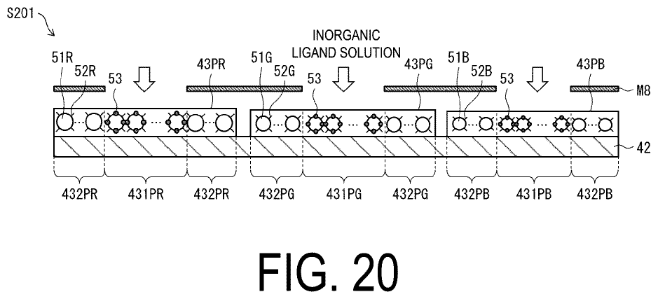

FIG. 20 is an enlarged cross-sectional view schematically illustrating a portion of the EML 43 of each color according to another example of a part of the light-emitting layer forming step (step S13) according to the present embodiment. Note that FIG. 20 illustrates the steps subsequent to the steps illustrated in FIG. 18.

In the present modified example, step S201 illustrated in FIG. 20 is performed instead of steps S181 to S184 illustrated in FIG. 19. In the present modified example, as illustrated in FIG. 20, a metal mask M8 is used as a mask for supplying the inorganic ligands 53 instead of the resist layer.

In the present modified example, the metal mask M8 is positioned with high accuracy, and regions (a region 432PR, a region 432PG, and a region 432PB) each forming the second region 432 of the subpixel peripheral portion of each of the subpixels SP are covered with the metal mask M8. Then, the inorganic ligands 53 are supplied to each of the first region planned formation region 431PR, the first region planned formation region 431PG, and the first region planned formation region 431PB, each of which forms the first region 431. As a result, the EML 43R, EML 43G and EML 43B illustrated in FIGS. 3 and 4 can be formed.

Note that, in the present modified example, a region other than the first region planned formation region 431PR in the red EML planned formation region 43PR is the region 432PR that forms the second region 432R of the EML 43R. Further, a region other than the first region planned formation region 431PG in the green EML planned formation region 43PG is the region 432PG that forms the second region 432G of the EML 43G. Further, a region other than the first region planned formation region 431PB in the blue EML planned formation region 43PB is the region 432PB that forms the second region 432B of the EML 43B.

The supply of the inorganic ligands 53 may be performed, for example, by dropping the inorganic ligand solution containing the inorganic ligands 53, or by spray coating the inorganic ligand solution using a mist sprayer or the like.

Note that in FIG. 20, a case is described, as an example, in which the supplies of the inorganic ligands 53 to the first region planned formation region 431PR, the first region planned formation region 431PG, and the first region planned formation region 431PB are performed simultaneously. However, the present modified example is not limited to this example, and for example, the EML 43R, the EML 43G, and the EML 43B may be formed in a manner described below.

In other words, for example, subsequent to step S164 illustrated in FIG. 18, first, the first inorganic ligand solution is supplied only to the first region planned formation region of the first light-emitting layer, using a metal mask having an opening only for the first region planned formation region of the first light-emitting layer. Thereafter, the second inorganic ligand solution is supplied only to the first region planned formation region of the second light-emitting layer, using a metal mask having an opening only for the first region planned formation region of the second light-emitting layer. Subsequently, the third inorganic ligand solution is supplied only to the first region planned formation region of the third light-emitting layer, using a metal mask having an opening only for the first region planned formation region of the third light-emitting layer. In this case also, inorganic ligand solutions of different types or having different concentrations may be used as the first inorganic ligand solution, the second inorganic ligand solution, and the third inorganic ligand solution.

### Third Modified Example

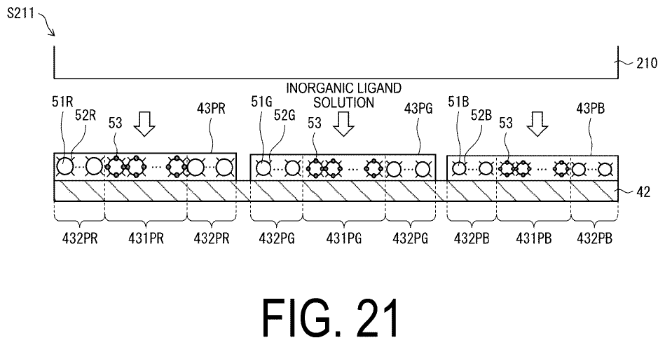

FIG. 21 is an enlarged cross-sectional view schematically illustrating a portion of the EML 43 of each color according to another example of a part of the light-emitting layer forming step (step S13) according to the present embodiment. Note that FIG. 21 illustrates steps subsequent to the steps illustrated in FIG. 18.

In the present modified example, step S211 illustrated in FIG. 21 is performed instead of steps S181 to S184 illustrated in FIG. 19. In the present modified example, as illustrated in FIG. 21, the ink-jet method is used for supplying the inorganic ligands 53.

In the present modified example, the inorganic ligands 53 are supplied from a nozzle of an ink-jet head 210 of an ink-jet device to each of the first region planned formation region 431PR, the first region planned formation region 431PG, and the first region planned formation region 431PB, each of which forms the first region 431.

In the present modified example, the viscosity and the dropping amount of the inorganic ligand solution containing the inorganic ligands 53 are adjusted so that the inorganic ligand solution does not spread to the regions (i.e., the region 432PR, the region 432PG, and the region 432PB) each of which forms the second region 432 of the subpixel peripheral portion of the subpixel SP. As a result, the EML 43R, EML 43G and EML 43B illustrated in FIGS. 3 and 4 can be formed.

Note that in FIG. 21, a case is described, as an example, in which the supplies of the inorganic ligands 53 to the first region planned formation region 431PR, the first region planned formation region 431PG, and the first region planned formation region 431PB are performed simultaneously. However, the present modified example is not limited to this example. The first inorganic ligand solution, the second inorganic ligand solution, and the third inorganic ligand solution may be used as the inorganic ligand solutions, the supplies of these inorganic ligand solutions may be performed with a time difference therebetween, and the viscosity and the dropping amount of each of these inorganic ligand solutions may be adjusted so that these inorganic ligand solutions do not spread to the portion that forms the second region 432 of each of the subpixels SP. In this case also, inorganic ligand solutions of different types or having different concentrations may be used as the first inorganic ligand solution, the second inorganic ligand solution, and the third inorganic ligand solution.

### Fourth Modified Example

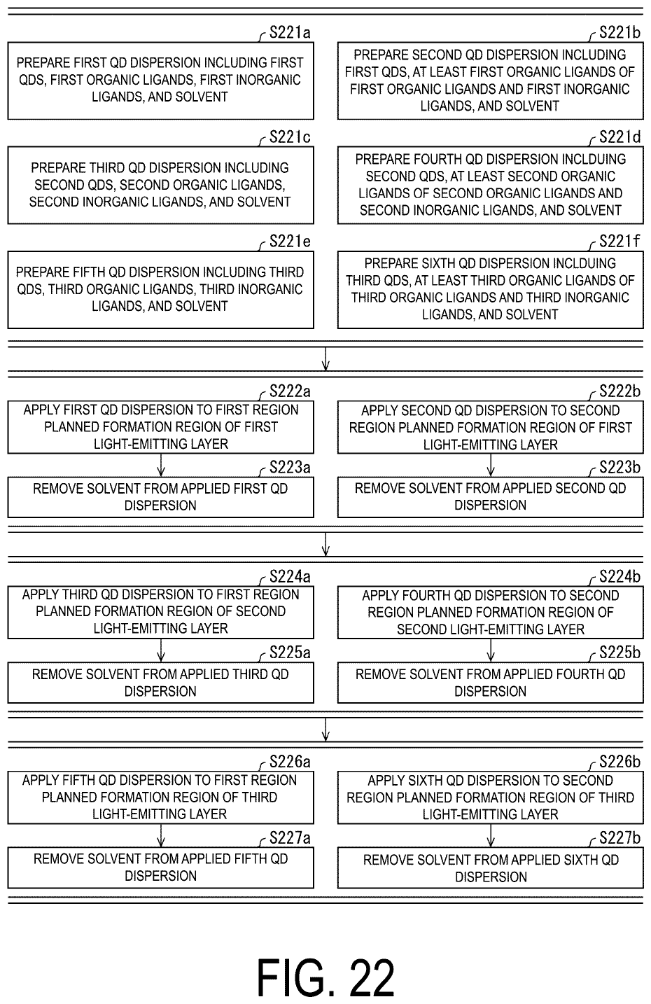

FIG. 22 is a flowchart illustrating an example of the light-emitting layer forming step (step S13) according to the present modified example.

As illustrated in FIG. 22, in the present modified example, first, as a QD dispersion of each color, a first QD dispersion is prepared (step S221a), and also, a second QD dispersion is prepared (step S221b), a third QD dispersion is prepared (step S221c), a fourth QD dispersion is prepared (step S221d), a fifth QD dispersion is prepared (step S221e), and a sixth dispersion is prepared (step S221f).

The first QD dispersion contains the first QDs, the first organic ligands, the first inorganic ligands, and a solvent. The second QD dispersion contains the first QDs, at least the first organic ligands of the first organic ligands and the first inorganic ligands, and a solvent. The number of the first inorganic ligands contained per unit volume in the second QD dispersion is less than the number of the first inorganic ligands contained per unit volume in the first QD dispersion.

Further, the third QD dispersion contains the second QDs, the second organic ligands, the second inorganic ligands, and a solvent. The fourth QD dispersion contains the second QDs, at least the second organic ligands of the second organic ligands and the second inorganic ligands, and a solvent. The number of the second inorganic ligands contained per unit volume in the fourth QD dispersion is less than the number of the second inorganic ligands contained per unit volume in the third QD dispersion.

Further, the fifth QD dispersion contains the third QDs, the third organic ligands, the third inorganic ligands, and a solvent. The sixth QD dispersion contains the third QDs, at least the third organic ligands of the third organic ligands and the third inorganic ligands, and a solvent. The number of the third inorganic ligands contained per unit volume in the sixth QD dispersion is less than the number of the third inorganic ligands contained per unit volume in the fifth QD dispersion.

Subsequently, after the first QD dispersion is applied to the first region planned formation region of the first light-emitting layer (step S222a), the solvent is removed from the applied first QD dispersion (step S223a). Further, prior to, subsequent to, or simultaneously with the above-described step S222a and the above-described step S223a, respectively, the second QD dispersion is applied to the second region planned formation region of the first light-emitting layer (step S222b), and then the solvent is removed from the applied second QD dispersion (step S223b).

Subsequently, after the third QD dispersion is applied to the first region planned formation region of the second light-emitting layer (step S224a), the solvent is removed from the applied third QD dispersion (step S225a). Further, prior to, subsequent to, or simultaneously with the above-described step S224a and the above-described step S225a, respectively, the fourth QD dispersion is applied to the second region planned formation region of the second light-emitting layer (step S224b), and then the solvent is removed from the applied fourth QD dispersion (step S225b).

Subsequently, after the fifth QD dispersion is applied to the first region planned formation region of the third light-emitting layer (step S226a), the solvent is removed from the applied fifth QD dispersion (step S227a). Further, prior to, subsequent to, or simultaneously with the above-described step S226a and the above-described step S227a, respectively, the sixth QD dispersion is applied to the second region planned formation region of the third light-emitting layer (step S226b), and then the solvent is removed from the applied sixth QD dispersion (step S227b).

Note that the first QD dispersion to the sixth QD dispersion can be applied to the above-described respective regions, for example, by separately applying the dispersions using the ink-jet method.

As a result, the EML 43R, EML 43G and EML 43B illustrated in FIGS. 3 and 4 can be formed.

### Third Embodiment

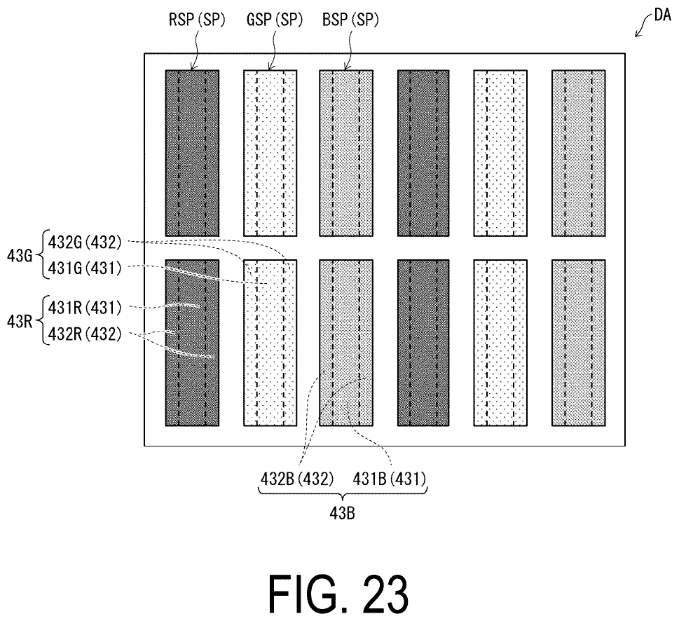

FIG. 23 is a plan view illustrating an example of a schematic configuration of the subpixel SP in the pixel region DA of the display device 1 according to the present embodiment, and illustrates another example of the schematic configuration of the subpixel SP in the pixel region DA of the display device 1 illustrated in FIG. 1. Note that in FIG. 23, the number of the subpixels SP is reduced for convenience of illustration.

As illustrated in FIG. 23, in the display device 1 according to the present embodiment, the second region 432 includes only the end portions adjacent to the subpixels SP each having a luminescent color different from that of the reference subpixel SP, among the end portions, of the EML 43 of the reference subpixel SP, adjacent to the other subpixels SP.

Optical crosstalk between the subpixels SP of the same color is less problematic than the color mixing. Thus, as illustrated in FIG. 23, if the second region 432 is provided in the end portion, of the EML 43, adjacent to the subpixel SP having the different luminescent color, the color mixing can be suppressed.

Note that even when the second region 432 is provided only in the end portion, of the EML 43, adjacent to the subpixel SP having the different luminescent color as described above, the shortest distance (Aa) from the end portion of the other subpixel SP adjacent to the second region 432 of the EML 43 of the reference subpixel SP, to the end portion of the first region 431 of the reference subpixel SP is preferably in the range of 2.0 μm or more and 8.5 μm or less.

### Fourth Embodiment

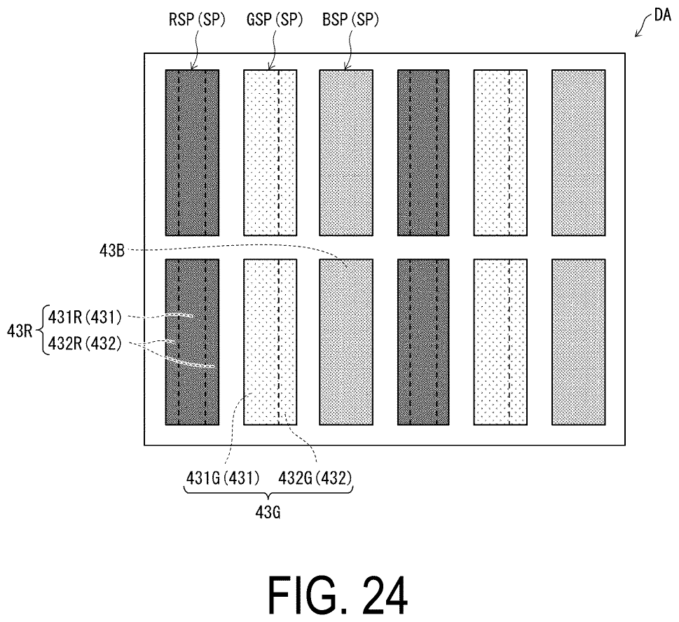

FIG. 24 is a plan view illustrating an example of a schematic configuration of the subpixel SP in the pixel region DA of the display device 1 according to the present embodiment, and illustrates yet another example of the schematic configuration of the subpixel SP in the pixel region DA of the display device 1 illustrated in FIG. 1. Note that in FIG. 24, the number of the subpixels SP is reduced for convenience of illustration.

As illustrated in FIG. 24, in the display device 1 according to the present embodiment, the second region 432 includes only the end portion adjacent to the subpixel SP that emits light having a shorter emission peak wavelength than that of the reference subpixel SP, among the end portions, of the EML 43 of the reference subpixel SP, adjacent to the other subpixels SP.

In general, the shorter the emission peak wavelength of the luminescent color, the higher the maximum drive voltage of the QLED (nano LED). Thus, when the light emission target subpixel SP adjacent to the reference subpixel SP has a longer emission peak wavelength than that of the reference subpixel SP, the reference subpixel SP having the shorter emission peak wavelength is unlikely to emit light due to the leakage current caused by driving of the subpixel having the longer wavelength.

As described in the first embodiment, when the emission peak wavelength (λ) in the subpixel RSP is 620 nm and Eg=2.0 eV, the emission threshold voltage of the subpixel RSP is ideally 2.0 V. Further, when the emission peak wavelength (λ) of the subpixel GSP is 530 nm and Eg=2.3 eV, the light-emission threshold voltage of the subpixel GSP is ideally 2.3 V. Further, when the emission peak wavelength (λ) of the subpixel BSP is 450 nm and Eg=2.8 eV, the light-emission threshold voltage of the subpixel BSP is ideally 2.8 V.

Therefore, in the display device 1 illustrated in FIG. 24, the second regions 432R are provided in both the end portion adjacent to the subpixel GSP and the end portion adjacent to the subpixel BSP in the EML 43R of the subpixel RSP. Further, in the EML 43G of the subpixel GSP, the second region 432G is provided only in the end portion adjacent to the subpixel BSP. However, the second region 432B is not provided in the EML 43B of the subpixel BSP.

Note that, in the example illustrated in FIG. 24, a region other than the second region 432R in the EML 43R is the first region 431R, and a region other than the second region 432G in the EML 43G is the first region 431G.

Even if the EML 43B does not include the second region 432B, as described above, color mixing in the subpixel BSP due to the leakage current from the subpixel RSP or the subpixel GSP is unlikely to occur. Thus, in the EML 43B, similarly to the first region 431B in the first to third embodiments, the ratio of the inorganic ligands 52B to the total number of the organic ligands 53B and the inorganic ligands 53B is preferably 8.2% or more and 100% or less, more preferably 8.2% or more and 82% or less, and even more preferably 41% or more and 82% or less. In this manner, in the EML 43B, there is no difference in the number of the inorganic ligands 53B per unit volume depending on the region, and the inorganic ligands 53B may be substantially uniformly contained in the entire EML 43B.

### Modified Example

In the first to third embodiments, a case is described, as an example, in which the first region 431 and the second region 432 are provided in the EML 43 of each of the subpixels SP. However, as illustrated in FIG. 24, as an example, in the display device 1 according to the disclosure, all the subpixels SP need not necessarily include the first region 431 and the second region 432.

In the display device 1 according to the disclosure, the EML 43 of at least one subpixel SP of the plurality of subpixels SP may include the first region 431 and the second region 432, the first region 431 may include the central portion of the EML 43 of the at least one subpixel SP, and the second region 432 may include at least one end portion among the end portions, of the EML 43 of the at least one subpixel SP, adjacent to the other subpixels SP adjacent to the at least one subpixel SP. As a result, in the at least one subpixel SP, it is possible to reduce the light emission of the second region 432 in the subpixel peripheral portion of the reference subpixel SP due to the leakage current from the light emission target subpixel SP adjacent to the at least one subpixel SP. As a result, in the at least one subpixel SP, the light emission efficiency can be improved by the inorganic ligand 53, and the optical crosstalk can be suppressed.

Therefore, for example, in the example illustrated in FIG. 23, the second region 432 may include only the end portion adjacent to the subpixel SP having a luminescent color different from that of the at least one subpixel SP, among the end portions, of the EML 43 of the at least one subpixel SP, adjacent to the other subpixels SP. As a result, in the at least one subpixel SP, it is possible to reduce the color mixing due to the leakage current.

Further, for example, in the example illustrated in FIG. 24, the second region 432 may include only the end portion adjacent to the subpixel SP having a shorter emission peak wavelength than that of the at least one subpixel SP, among the end portions, of the EML 43 of the at least one subpixel SP, adjacent to the other subpixels SP. As a result, in the at least one subpixel SP, it is possible to achieve improvement in the light emission efficiency and reliability by the inorganic ligand 53 and reduction of the color mixing due to the leakage current.

Further, the second region 432 may include the end portion adjacent to the subpixel SP having the same luminescent color as that of the at least one subpixel SP, among the end portions, of the EML 43 of the at least one subpixel SP, adjacent to the other subpixels SP. As a result, in the at least one subpixel SP, it is possible to reduce the light emission due to the leakage current from the adjacent subpixel SP, and thus to display a high-resolution image. For example, in the example illustrated in FIG. 2, the second region 432 may be formed to include all the end portions, of the EML 43 of the at least one subpixel SP, adjacent to the other subpixels SP, so as to surround the first region 431.

Therefore, in the manufacturing method for the display device 1 according to the disclosure, in the light-emitting layer forming step, the EML 43 having a configuration described in the following (i) to (iii) may be formed as a light-emitting layer in the at least one subpixel SP of the plurality of subpixels SP. (i) The EML 43 includes the first region 431 and the second region 432. (ii) The first region 431 includes a central portion of the light-emitting layer of the at least one subpixel SP. (iii) The second region 432 includes at least one end portion among end portions, of the light-emitting layer of the at least one subpixel SP, adjacent to other subpixels SP adjacent to the at least one subpixel SP. As a result, in the at least one subpixel SP, it is possible to improve the light emission efficiency by the inorganic ligand 53, and also to manufacture the display device 1 that can suppress the optical crosstalk.

### Fifth Embodiment

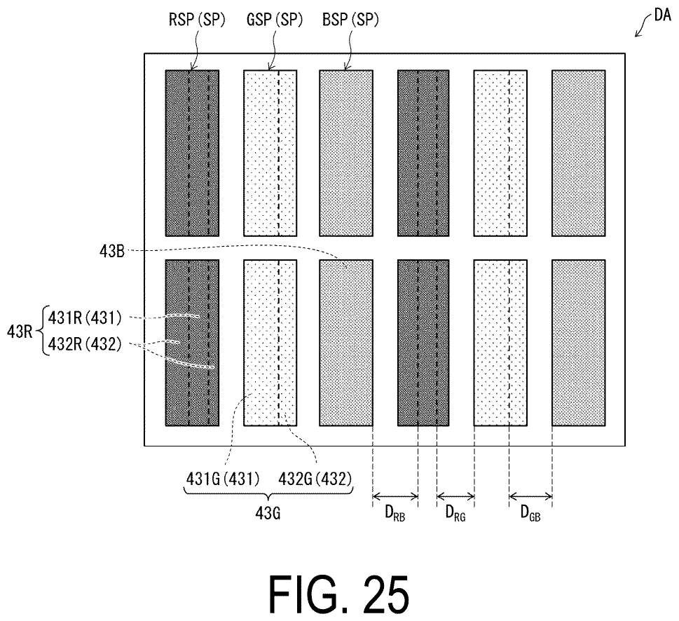

FIG. 25 is a plan view illustrating an example of a schematic configuration of the subpixel SP in the pixel region DA of the display device 1 according to the present embodiment, and illustrates yet another example of the schematic configuration of the subpixel SP in the pixel region DA of the display device 1 illustrated in FIG. 1. Note that in FIG. 25, the number of the subpixels SP is reduced for convenience of illustration.

The display device 1 illustrated in FIG. 25 has the same configuration as the display device 1 illustrated in FIG. 24, except for the following points. In the display device 1 illustrated in FIG. 25, the shortest distance (Aa) from the end portion of the subpixel SP adjacent to the second region 432 of the EML 43 of the reference subpixel SP and having a different luminescent color from that of the reference subpixel SP, to the end portion of the first region 431 of the reference subpixel SP increases as the band gap difference between the EML 43 of the reference subpixel SP and the EML 43 of the subpixel SP having the different luminescent color increases.

As described above, when the band gap (Eg) of the subpixel RSP is 2.0 eV, the band gap (Eg) of the subpixel GSP is 2.3 eV, and the band gap (Eg) of the subpixel BSP is 2.8 eV, if the band gap difference between the subpixel RSP and the subpixel BSP is defined as Eg(RB), Eg(RB)=0.8 eV is established. Further, when the band gap difference between the subpixel GSP and the subpixel BSP is defined as Eg(GB), Eg(GB)=0.5 eV is established. Further, when the band gap difference between the subpixel RSP and the subpixel GSP is defined as Eg(RG), Eg(RG)=0.3 eV is established. Therefore, the differences in the band gap between the subpixels SP having the different luminescent colors satisfy Eg(RB)>Eg(GB)>Eg(RG).

In this case, the light emission threshold voltage (Vth) changes depending on the maximum drive voltage (Vdm) (corresponding to the band gap) of the subpixel SP of each color. Therefore, Vdm−Vth changes depending on the luminescent color of each of the subpixels SP. Thus, it is desirable that those changes in Vdm−Vth due to the band gap difference are reflected on the shortest distance (Δa) from the end portion of the subpixel SP having the luminescent color different from that of the reference subpixel SP and adjacent to the second region 432 of the EML 43 of the reference subpixel SP, to the end portion of the first region 431 of the reference subpixel SP.

In the present embodiment, the shortest distance (Δa) is calculated by changing Vdm−Vth, which is 1 V in Equation (1) illustrated in the first embodiment, to a value obtained by adding the difference in the band gap thereto. In other words, in the first embodiment, Vdm−Vth is always 1 V regardless of the luminescent color of the subpixel SP adjacent to the reference subpixel SP, but in the present embodiment, the difference in the maximum drive voltage (Vdm) due to the luminescent color of the subpixel SP adjacent to the reference subpixel SP is reflected.

Specifically, Vdm−Vth between the subpixel RSP and the subpixel BSP is set such that Vdm−Vth=1.8 V. Further, Vdm−Vth between the subpixel GSP and the subpixel BSP is set such that Vdm−Vth=1.5 V. Further, Vdm−Vth between the subpixel RSP and the subpixel GSP is set such that Vdm−Vth=1.3 V.

Further, the shortest distance (Δa) from an end portion of the subpixel BSP adjacent to the second region 432R of the EML 43R in the subpixel RSP to an end portion of the first region 431R of that EML 43R is defined as D_{RB}. Further, the shortest distance (Δa) from an end portion of the subpixel GSP adjacent to the second region 432R of the EML 43R in the subpixel RSP to an end portion of the first region 431R of that EML 43R is defined as D_{RG}. Further, the shortest distance (Δa) from an end portion of the subpixel BSP adjacent to the second region 432G of the EML 43G in the subpixel GSP to an end portion of the first region 431G of that EML 43G is defined as D_{GB}.

In this case, it is preferable that D_{RG}<D_{GB}<D_{RB}, 2.3 μm≤D_{RG}≤7.2 μm, 2.4 μm≤D_{GB}≤7.7 μm, and 2.7 μm≤D_{RB}≤8.5 μm.

In this manner, by increasing the shortest distance (Δa) as the band gap difference between the EML 43 of the reference subpixel SP and the EML 43 of the subpixel SP having the luminescent color different from that of the reference subpixel SP becomes greater, it is possible to efficiently suppress the color mixing in portions in which the difference in the maximum drive voltage is great.

### Modified Example

Note that FIG. 25 illustrates a case, as an example, in which Aa increases as the band gap difference increases between the EML 43 of the reference subpixel SP and the EML 43 of the subpixel SP adjacent to the reference subpixel SP and having the luminescent color different from that of the reference subpixel SP, in the display device 1 illustrated in FIG. 24. However, the present embodiment is not limited to this example.

For example, in the display device 1 illustrated in FIG. 2 or 23, Δa may be increased as the band gap difference increases between the EML 43 of the reference subpixel SP and the EML 43 of the subpixel SP adjacent to the reference subpixel SP and having the luminescent color different from that of the reference subpixel SP.

Further, the display device 1 may have a configuration in which the shortest distance (Δa) from the end portion of the subpixel SP adjacent to the second region 432 of the EML 43 in the at least one subpixel SP and having the luminescent color different from that of the at least one subpixel SP, to the end portion of the first region 431 of the EML 43 of the at least one subpixel SP increases as the band gap difference between the EML 43 of the at least one subpixel SP and the EML 43 of the subpixel SP having the different luminescent color increases.

### Sixth Embodiment

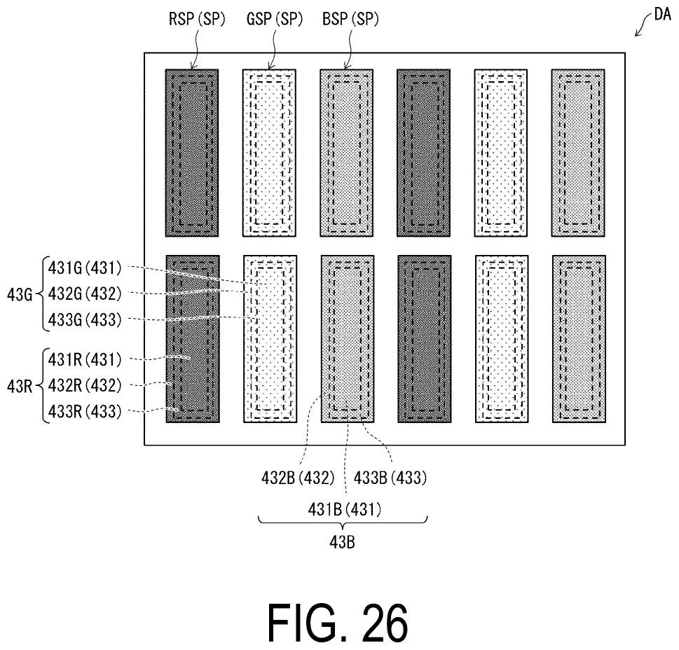

FIG. 26 is a plan view illustrating an example of a schematic configuration of the subpixel SP in the pixel region DA of the display device 1 according to the present embodiment, and illustrates yet another example of the schematic configuration of the subpixel SP in the pixel region DA of the display device 1 illustrated in FIG. 1. Note that in FIG. 26, the number of the subpixels SP is reduced for convenience of illustration.

The display device 1 illustrated in FIG. 26 has the same configuration as that of the display device 1 illustrated in FIG. 2, except for the following points. As illustrated in FIG. 26, the display device 1 illustrated in FIG. 26 includes a third region 433R between the first region 431R and the second region 432R in the EML 43R of the subpixel RSP. Further, a third region 433G is provided between the first region 431G and the second region 432G in the EML 43G of the subpixel GSP. Further, a third region 433B is provided between the first region 431B and the second region 432B in the EML 43B of the subpixel BSP.

The third region 433R includes the QDs 51R, the organic ligands 52R, and the inorganic ligands 53R, and is a region in which the number of the inorganic ligands 53R contained per unit volume is less than the number of the inorganic ligands 53R contained per unit volume in the first region 431R and is greater than the number of the inorganic ligands 53R contained per unit volume in the second region 432R.

The third region 433G includes the QDs 51G, the organic ligands 52G, and the inorganic ligands 53G, and is a region in which the number of the inorganic ligands 53G contained per unit volume is less than the number of the inorganic ligands 53G contained per unit volume in the first region 431G and is greater than the number of the inorganic ligands 53G contained per unit volume in the second region 432G.

The third region 433B includes the QDs 51B, the organic ligands 52B, and the inorganic ligands 53B, and is a region in which the number of the inorganic ligands 53B contained per unit volume is less than the number of the inorganic ligands 53B contained per unit volume in the first region 431B and is greater than the number of the inorganic ligands 53B contained per unit volume in the second region 432B.

Note that, hereinafter, when there is no particular need to distinguish the third region 433R, the third region 433G, and the third region 433B from one another, these are collectively referred to simply as “third region 433”.

FIG. 26 illustrates a case, as an example, in which the third region 433 is provided between the first region 431 and the second region 432 in the display device 1 illustrated in FIG. 2. However, the present embodiment is not limited to this example, and for example, the third region 433 may be provided between the first region 431 and the second region 432 in the display device 1 illustrated in FIG. 23, 24, or 26.

Further, the display device 1 may have a configuration in which the third region 433 is provided between the first region 431 and the second region 432 in the EML 43 of the at least one subpixel SP.

By providing the third region 433 between the first region 431 and the second region 432 in this manner, it is possible to increase the light emission efficiency of the subpixel peripheral portion as compared with a case in which the third region 433 is not provided (in other words, a case in which only the second region 432 is provided in the subpixel peripheral portion).

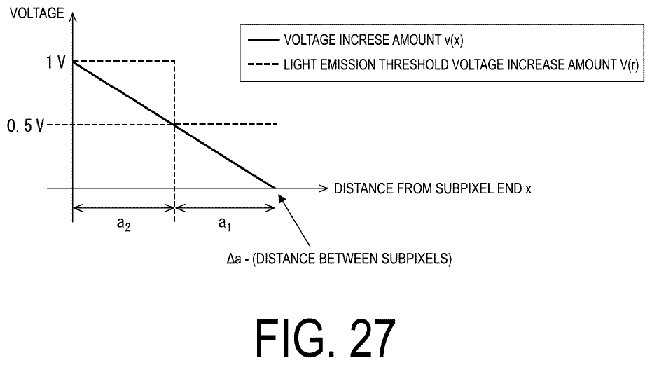

FIG. 27 is a graph showing a relationship, in the reference subpixel SP, between a distance x from the subpixel end, a voltage increase amount v(x) of the reference subpixel SP caused by driving of the light emission target subpixel SP adjacent to the reference subpixel SP, and a light emission threshold voltage increase amount V(r) of the reference subpixel SP when the ratio of the inorganic ligands 53 to the total number of the organic ligands 52 and the inorganic ligands 53 is r.

Here, the distance x from the subpixel end in the reference subpixel SP refers to a distance in a direction from an end portion of the reference subpixel SP toward a central portion of the reference subpixel SP. When the width of the second region 432 and the width of the third region 433 are a1 and a2, respectively, the voltage increase amount v(x) of the reference subpixel SP caused by the driving of the subpixel SP adjacent to the reference subpixel SP is expressed by v(x)=1×(1−x/(a1+a2)) [unit: V]. Note that a1+a2 is equal to a value obtained by subtracting the distance between the subpixels SP from Aa described in the first embodiment.

On the other hand, when the ratio of the inorganic ligands 53 to the total number of the organic ligands 52 and the inorganic ligands 53 is r, the light emission threshold voltage increase amount V(r) of the reference subpixel SP is given by Equation (2) illustrated in the first embodiment.

In order not to cause the second region 432 and the third region 433 to emit light due to the driving of the light emission target subpixel SP adjacent to the reference subpixel SP, it is desirable that v(x)≤V(r) is satisfied in the range of 0≤x≤(a1+a2).

The greater the value of v(x), the greater the leakage current and the higher the light emission luminance. However, if V(r) is v(x) or greater as illustrated in FIG. 27, the light-emitting element ES whose light emission threshold voltage is V(r) cannot be caused to emit light by the voltage of v(x). For this reason, as long as v(x)≤V(r) is satisfied, crosstalk between the subpixels SP does not become a problem.

In the present embodiment, v(x) is defined in consideration of a voltage drop from the light emission target subpixel SP adjacent to the reference subpixel SP to the reference subpixel SP. As illustrated in FIG. 27, v(x) decreases in proportion to the reciprocal of the value obtained by subtracting the distance between the subpixels from Aa described in the first embodiment. Thus, by changing the ratio r of the inorganic ligands 53 in a stepwise manner in the subpixel peripheral portion of the reference subpixel SP, the light emission due to the leakage current from the adjacent subpixel can be suppressed, while the light emission efficiency of the subpixel peripheral portion can be increased as compared with the case in which only the second region 432 is provided in the subpixel peripheral portion).

In the present embodiment, when the ratio of the inorganic ligands 53 to the total number of the organic ligands 52 and the inorganic ligands 53 in the second region 432 is defined as r2, the light emission threshold voltage increase amount of the second region 432 is defined as V(r2), and v(x) is v(0) when x=0, it is desirable that V(r2) satisfies v(0)≤V(r2) with respect to r2 in order not to cause the second region 432 to emit light due to the driving of the subpixel SP adjacent to the reference subpixel SP.

Here, v(0) satisfies v(0)=1V. Thus, in order not to cause the second region 432 to emit light due to the driving of the subpixel SP adjacent to the reference subpixel SP, it is desirable that V(r2)≥1V. Therefore, in Equation (2) described above, when calculation is performed assuming that r=r2, it is desirable that r2≤0.41, and the ratio r2 of the inorganic ligands 53 in the second region 432 is 0% or more and 41% or less.

Further, as described above, in the range of 0≤x≤(a1+a2), when the width of the second region 432 and the width of the third region 433 are equal to each other and a1=a2, and when the ratio of the inorganic ligands 53 to the total number of the organic ligands 52 and the inorganic ligands 53 in the third region 433 is defined as r3, the light emission threshold voltage increase amount of the third region 433 is defined as V(r3), and v(x) is set to v(0.5) that is obtained when x=0.5 at a boundary position between the third region 433 and the second region 432, it is desirable that V(r3) satisfies v(0.5)≤V(r3) with respect to r3 in order not to cause the third region 433 to emit light due to the driving of the subpixel SP adjacent to the reference subpixel SP.

Here, v(0.5) satisfies v(0.5)=0.5 V. Thus, in order not to cause the third region 433 to emit light due to the driving of the subpixel SP adjacent to the reference subpixel SP, it is desirable that V(r3)≥0.5V. Therefore, in Equation (2) described above, when calculation is performed assuming that r=r3, it is desirable that r3 satisfies r3≤0.62. Thus, it is desirable that the ratio r3 of the inorganic ligands 53 in the third region 433 is 41% or more and 62% or less.

Further, as described in the first embodiment, the ratio of the inorganic ligands 53 to the total number of the organic ligands 52 and the inorganic ligands 53 in the first region 431 may be 100%. However, the maximum ratio of the inorganic ligands 53 to the total number of the organic ligands 52 and the inorganic ligands 53, which is preferable for preventing the aggregation of the QDs 51, is 82%.

Therefore, when the ratio of the inorganic ligands 53 to the total number of the organic ligands 52 and the inorganic ligands 53 in the first region 431 is r1, as described above, r2<r3<r1 is satisfied, and it is sufficient that r1 to r3 satisfy the above-described relationship. However, r1 is preferably in a range of 62% or more and 100% or less, and more preferably in a range of 62% or more and 82% or less. Further, r3 is preferably in a range of 41% or more and 62% or less, and r2 is preferably in a range of 0% or more and 41% or less (however, r2<r3<r1).

A manufacturing method for the display device 1 according to the present embodiment is different from the manufacturing method for the display device 1 according to the first to fifth embodiments in that the EML 43, which further includes the third region 433 between the first region 431 and the second region 432, is formed as the light-emitting layer of the at least one subpixel SP of the plurality of subpixels SP at the light-emitting layer forming step.

Note that, in order to form the third region 433 between the first region 431 and the second region 432, the inorganic ligands 53 may be supplied to a third region planned formation region of the EML 43 so that r2<r3<r1 is satisfied as described above. Note that, here, the third region planned formation region refers to a region in which the third region 433 is finally formed in the EML 43.

Further, as a method for supplying the inorganic ligands 53 to the third region planned formation region of the EML 43 so that r2<r3<r1 is satisfied as described above, a method similar to the method for supplying the inorganic ligands 53 to the second region planned formation region so that r2<r1 is satisfied, in the first embodiment or the second embodiment can be used.

### Seventh Embodiment

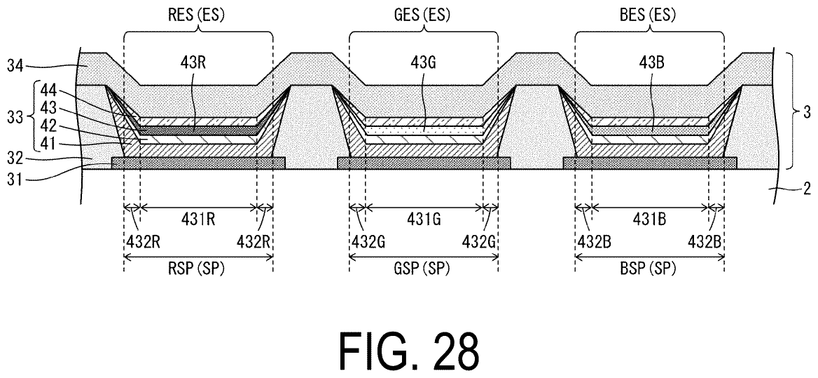

FIG. 28 is a cross-sectional view illustrating an example of a schematic configuration of main portions of the display device 1 according to the present embodiment. Note that FIG. 28 illustrates another example of the cross section taken along the line A-A′ illustrated in FIG. 2.

The display device 1 illustrated in FIG. 28 is different from the display device 1 illustrated in FIG. 3 in that the HIL 41, the HTL 42, and the ETL 44 are partitioned by the bank 32 between the subpixels SP, and the HIL 41, the HTL 42, and the ETL 44 are formed in an island shape for each of the subpixels SP.

Even if at least one of the HIL41, the HTL 42, or the ETL 44 is partitioned by the bank 32 or the like between the subpixels SP in such a manner as described above, there is still a possibility that an unexpected leak path is generated between the subpixels SP due to scattering of a material solution of each layer onto the bank 32, foreign matters on the bank 32, or the like. However, even in such a case, by forming at least the first region 431 and the second region 432 of the EML 43, it is possible to reliably suppress the crosstalk between the subpixels SP.

Note that FIG. 28 illustrates a case, as an example, in which the HTL 41, the HTL 42, and the ETL 44 are formed in the island shape for each of the subpixels SP. However, when the display device 1 has, for example, a known structure as illustrated in FIG. 28, the same effect can be obtained even when the ETL 44 is a common layer common to all the subpixels SP, and the HIL 41 and the HTL 42 are formed in the island shape. Further, when the display device 1 has, for example, an inverted structure, the same effect can be obtained even when the HIL 41 and the HTL 42 are common layers common to all the subpixels SP, and the ETL 44 is formed in the island shape.

### Eighth Embodiment

In the above-described embodiments, particularly in the first and second embodiments, as illustrated in FIG. 4 and the like, a case is described, as an example, in which each of the first region 431R, the first region 431G, and the first region 431B includes both the organic ligand 52 and the inorganic ligand 53 as the ligand. However, as described above, it is sufficient that the first region 431R, the first region 431G, and the first region 431B include the QD 51 and at least the inorganic ligand 53 of the organic ligand 52 and the inorganic ligand 53. Therefore, in the present embodiment, a case will be described in which the first region 431R, the first region 431G, and the first region 431B include the QD 51 and the inorganic ligand 53 but do not include the organic ligand 52.

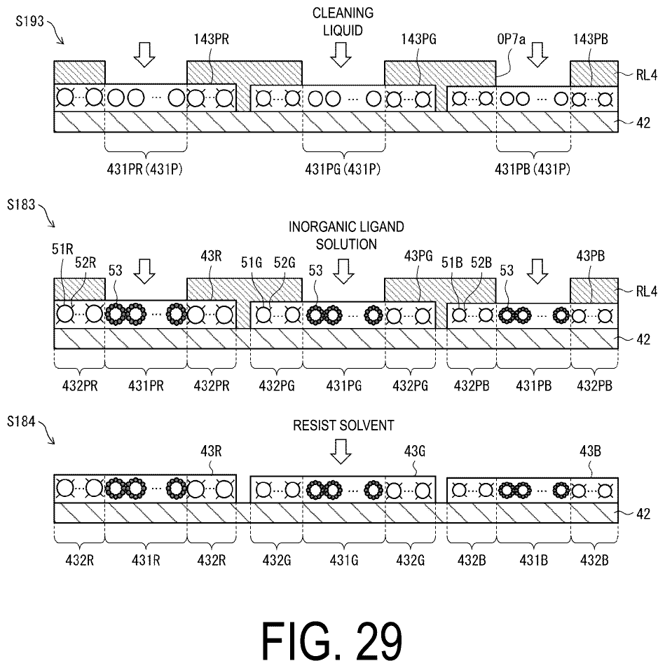

FIG. 29 is a cross-sectional view illustrating an example of a part of the light-emitting layer forming step (step S13) according to the present embodiment. FIG. 29 illustrates steps subsequent to the fourth resist layer developing step (step S182) in the fourth resist layer patterning step (step S192) illustrated in FIG. 19.

In a method illustrated in FIG. 29, subsequent to step S192 and prior to step S183 (inorganic ligand supplying step), the first region planned formation region 431PR, the first region planned formation region 431PG, and the first region planned formation region 431PB exposed from the openings OP7a formed in the fourth resist layer RL4 are cleaned with a cleaning liquid. As a result, the organic ligands 52 included in the first region planned formation region 431PR, the first region planned formation region 431PG, and the first region planned formation region 431PB are removed (step S193, an organic ligand removing process, a cleaning step). Note that, hereinafter, when there is no particular need to distinguish the first region planned formation region 431PR, the first region planned formation region 431PG, and the first region planned formation region 431PB from one another, they are collectively referred to simply as “first region planned formation region 431P”.

The removal rate of the organic ligands 52 can be adjusted by, for example, the cleaning time, the supply amount of the cleaning liquid, or the like. In the present embodiment, as an example, at step S193, cleaning is performed until the organic ligands 52 are completely removed. However, at step S193, only some of the organic ligands 52 may be removed. By removing at least some of the organic ligands 52 in this manner, the number of the organic ligands 52 contained per unit volume in the first region 431 can be made less than the number of the organic ligands 52 contained per unit volume in the second region 432. As a result, the number of the inorganic ligands 53G contained per unit volume in the first region 431 can be made greater than the number of the organic ligands 52 contained per unit volume in the second region 432. Therefore, by removing at least some of the organic ligands 52 in this manner, it is possible to reduce the amount of the organic ligands 52 coordinated to the QD 51 of the first region planned formation region 431P and to increase the number of the inorganic ligands 53G coordinated to the QD 51 at step S183.

Any solvent may be used as the cleaning liquid as long as it can remove the organic ligands 52 contained in the first region planned formation region 431P. More specifically, the cleaning liquid may be any solvent that dissolves the organic ligands 52 coordinated to the QD 51, and that dissolves the excess organic ligands 52 not coordinated to the QD 51. Examples of the cleaning liquid include alcohols such as methanol and ethanol.

Note that a waste cleaning liquid used for the cleaning and containing the organic ligands 52 may be recovered if necessary. The waste cleaning liquid contains only the solvent used as the cleaning liquid and the organic ligands 52. Therefore, by recovering the waste cleaning liquid, the organic ligands 52 contained in the waste cleaning liquid can be reused.

Subsequently, in the same manner as at step S183 illustrated in FIG. 19, the inorganic ligand solution containing the inorganic ligands 53 is applied to each of the first region planned formation regions 431P exposed from the openings OP7a. As a result, the inorganic ligands 53B are supplied to each of the first region planned formation region 431PR, the first region planned formation region 431PG, and the first region planned formation region 431PB (step S183, an inorganic ligand supplying step).

As a result, the first region 431R is formed in the first region planned formation region 431PR, the first region 431G is formed in the first region planned formation region 431PG, and the first region 431B is formed in the first region planned formation region 431PB. Then, a region other than the first region planned formation region 431PR in the red QD containing layer pattern 143PR becomes the second region 432R of the EML 43R. Further, a region other than the first region planned formation region 431PG in the green QD containing layer pattern 143PG becomes the second region 432G of the EML 43G. Further, a region other than the first region planned formation region 431PB in the blue QD containing layer pattern 143PB becomes the second region 432B of the EML 43B.

Thereafter, after removing and drying the solvent contained in the inorganic ligand solution applied to the first region planned formation region 431PR, the first region planned formation region 431PG, and the first region planned formation region 431PB, the fourth resist layer RL4 is removed by the resist solvent (step S184, a fourth resist layer removing step).

As a result, on the HTL 42, the plurality of island-shaped EMLs 43 are formed that include the EML 43R including the first region 431R and the second region 432R, the EML 43G including the first region 431G and the second region 432G, and the EML 43B including the first region 431B and the second region 432B. However, in FIG. 29, the organic ligands 52 are completely removed at step S193. Thus, in FIG. 29, by performing step S183 and step S184 subsequent to step S193, it is possible to form the first region 431R, the first region 431G, and the first region 431B each of which includes the QDs 51 and the inorganic ligands 53 but does not include the organic ligands 52.

As described above, according to the present embodiment, the ratio between the organic ligands 52 and the inorganic ligands 53 in the first region 431 can be easily adjusted by performing the organic ligand removing step.

### First Modified Example

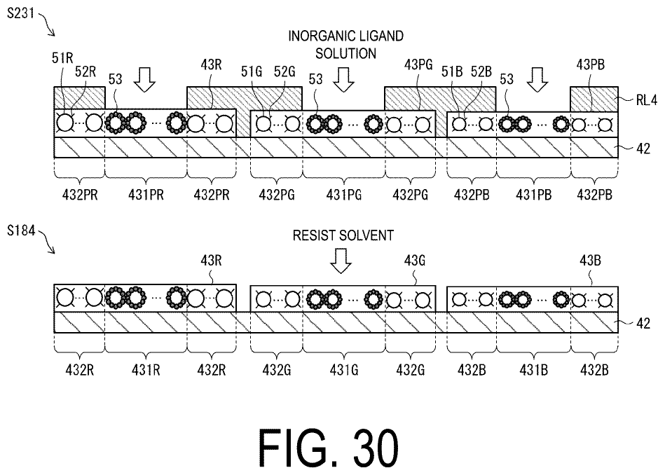

FIG. 30 is a cross-sectional view illustrating an example of a part of the light-emitting layer forming step (step S13) according to the present embodiment. FIG. 30 illustrates steps subsequent to the fourth resist layer developing step (step S182) in the fourth resist layer patterning step (step S192) illustrated in FIG. 19.

In a method illustrated in FIG. 30, subsequent to step S192, an excessive amount of the inorganic ligands 53 is supplied to each of the first region planned formation regions 431P exposed from the openings OP7a formed in the fourth resist layer RL4. As a result, the organic ligands 52 in the first region planned formation regions 431P are replaced by the inorganic ligands 53 (ligand substitution) (step S231, a ligand substitution step, an inorganic ligand supplying step).

Step S231 is the same as step S183 illustrated in FIG. 19, except that the inorganic ligand solution containing the inorganic ligands 53 is applied (supplied) to the first region planned formation region 431P until all the organic ligands 52 contained in the first region planned formation region 431P are replaced by the inorganic ligands 53.

The organic ligand 52 has a weaker coordination force to the QD 51 than the inorganic ligand 53, and easily becomes detached from the QD 51. Therefore, in the inorganic ligand supplying step, by supplying the excessive amount of the inorganic ligands 53 (in particular, excessive inorganic ligand solution to the first region planned formation region 431P, the organic ligand 52 coordinated to the QD 51 in the first region planned formation region 431P can be replaced by the inorganic ligand 53.

Note that the supply amount and concentration of the inorganic ligand solution, the time required for the ligand substitution, and the like may be appropriately set so that the ratio between the organic ligands 52 and the inorganic ligands 53 in the first region 431 becomes a desired ratio, and are not particularly limited.

Thereafter, also in the present modified example, the solvent contained in the inorganic ligand solution applied to the first region planned formation region 431P is removed and dried, and then, the fourth resist layer RL4 is removed by the resist solvent (step S184, the fourth resist layer removing step).

As a result, also in the present modified example, it is possible to form the first region 431R, the first region 431G, and the first region 431B, each of which includes the QD 51 and the inorganic ligand 53 but does not include the organic ligand 52, for example. Note that, of course, also in the present modified example, only some of the organic ligands 52 may be replaced by the inorganic ligands 53 at step S231.

Further, subsequent to step S231 and prior to step S184, if necessary, a cleaning step may be performed in which the excess inorganic ligands 53 not coordinated to the QD 51 and the organic ligands 52 contained in the first region planned formation region 431P are removed by cleaning using a cleaning liquid. In this case, the cleaning liquid used in the cleaning step may be any solvent that dissolves the organic ligands 52 coordinated to the QD 51, and that dissolves the excess organic ligands 52 and the excess inorganic ligands 53 not coordinated to the QD 51. Examples of the cleaning liquid include alcohols such as methanol and ethanol.

As described above, according to the present modified example, the ratio between the organic ligands 52 and the inorganic ligands 53 in the first region 431 can be easily adjusted by supplying the inorganic ligand solution containing the inorganic ligands 53 to the first region planned formation region 431P to perform the ligand substitution.

### Third Modified Example

In FIG. 29 and FIG. 30, a case is described, as an example, in which the organic ligand removing step (cleaning step) or the ligand substitution step (inorganic ligand supplying step) is performed simultaneously in the first region planned formation region 431PR, the first region planned formation region 431PG, and the first region planned formation region 431PB. However, the present embodiment is not limited to this example, and the organic ligand removing step (cleaning step) or the ligand substitution step (inorganic ligand supplying step) may be independently performed on each of the first region planned formation region 431PR, the first region planned formation region 431PG, and the first region planned formation region 431PB.

For example, subsequent to step S52 illustrated in FIG. 11, and prior to step S37 (first inorganic ligand supplying step) is performed, at least some of the organic ligands 52R in the first region planned formation region 431PR may be removed in the same manner as at step S193. Then, subsequent to step S82 illustrated in FIG. 13, and prior to step S67 (second inorganic ligand supplying step) is performed, at least some of the organic ligands 52G in the first region planned formation region 431PG may be removed in the same manner as at step S193. Then, subsequent to step S112 illustrated in FIG. 15, and prior to step S97 (third inorganic ligand supplying step) is performed, at least some of the organic ligands 52B in the first region planned formation region 431PB may be removed in the same manner as at step S193. Of course, even when the metal mask M8 is used as the mask as illustrated in FIG. 20, at least some of the organic ligands 52 in the first region planned formation region 431P may be removed before supplying the inorganic ligands 53 at step S201 in the same manner as at step S193. Further, instead of or in addition to the method described above, for example, when the inorganic ligands 53 are supplied at step S37, step S67, step S97, step S201, or the like, ligand substitution of the organic ligands 52 with the excess inorganic ligands 53 may be performed.

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in each of the embodiments.

### REFERENCE SIGNS LIST

1 Display device
31 Anode electrode (first electrode)
33 Function layer
43, 43B, 43G, 43R EML (light-emitting layer)
34 Cathode electrode (second electrode)
43PR Red EML planned formation region (first light-emitting layer planned formation region)
43PG Green EML planned formation region (second light-emitting layer planned formation region)
43PB Blue EML planned formation region (third light-emitting layer planned formation region)
51, 51R, 51G, 51B QD (quantum dot)
52, 52R, 52G, 52B Organic ligand
53, 53R, 53G, 53B Inorganic ligand
143R Red QD containing layer (first quantum dot containing layer)
143G Green QD containing layer (second quantum dot containing layer)
143B Blue QD containing layer (third quantum dot containing layer)
431, 431R, 431G, 431B First region
432, 432R, 432G, 432B Second region
433, 433R, 433G, 433B Third region
M8 Metal mask
OP2a Opening (first opening)
OP4a Opening (second opening)
OP6a Opening (third opening)
RL1 First resist layer
RL2 Second resist layer
RL3 Third resist layer
RL4 Fourth resist layer
SP Subpixel

1. A display device comprising:
a plurality of subpixels,
wherein each of the plurality of subpixels includes a first electrode, a second electrode, and a function layer provided between the first electrode and second electrode and including at least a light-emitting layer,
the light-emitting layer of at least one subpixel of the plurality of subpixels includes
a first region including a quantum dot and including, of an organic ligand and an inorganic ligand, at least the inorganic ligand, and
a second region including the quantum dot and including, of the organic ligand and the inorganic ligand, at least the organic ligand, a number of a plurality of the inorganic ligands included per unit volume in the second region being less than a number of the plurality of inorganic ligands included per unit volume in the first region,
the first region includes a central portion of the light-emitting layer of the at least one subpixel, and
the second region includes at least one end portion among end portions, of the light-emitting layer of the at least one subpixel, adjacent to other subpixels of the plurality of subpixels respectively adjacent to the at least one subpixel.

2. The display device according to claim 1,
wherein the plurality of subpixels include subpixels having different luminescent colors, and
the second region includes only an end portion adjacent to the subpixel having a luminescent color different from the luminescent color of the at least one subpixel, among the end portions, of the light-emitting layer of the at least one subpixel, adjacent to the other subpixel.

3. The display device according to claim 1,
wherein the plurality of subpixels include subpixels having different luminescent colors, and
the second region includes only an end portion adjacent to the subpixel that emits light having a shorter emission peak wavelength than an emission peak wavelength of the at least one subpixel, among the end portions, of the light-emitting layer of the at least one subpixel, adjacent to the other subpixel.

4. The display device according to claim 1,
wherein the plurality of subpixels include a plurality of subpixels having the same luminescent color, and
the second region includes an end portion adjacent to the subpixel having the same luminescent color as the luminescent color of the at least one subpixel, among the end portions, of the light-emitting layer of the at least one subpixel, adjacent to the other subpixel.

5. The display device according to claim 1,
wherein the second region includes all the end portions, of the light-emitting layer of the at least one subpixel, adjacent to the other subpixels, and is formed surrounding the first region.

6. The display device according to claim 1,
wherein a shortest distance from an end portion of the other subpixel adjacent to the second region of the light-emitting layer of the at least one subpixel to an end portion of the first region of the at least one subpixel is in a range of 2.0 μm or more and 8.5 μm or less.

7-8. (canceled)

9. The display device according to claim 1,
wherein the inorganic ligand is an ion of a halogen atom.

10. The display device according to claim 1,
wherein the inorganic ligand is a fluoride ion.

11. The display device according to claim 1,
wherein a ratio of the plurality of inorganic ligands to a total number of a plurality of the organic ligands and the plurality of inorganic ligands in the second region is in a range of 0% or more and 41% or less.

12. The display device according to claim 1,
wherein the ratio of the plurality of inorganic ligands to the total number of a plurality of the organic ligands and the plurality of inorganic ligands in the second region is in a range of 0% or more and 8.2% or less.

13. The display device according to claim 1,
wherein the ratio of the plurality of inorganic ligands to the total number of a plurality of the organic ligands and the plurality of inorganic ligands in the first region is in a range of 8.2% or more and 100% or less.

14. The display device according to claim 1,
wherein the first region includes the organic ligand, and
the ratio of the plurality of inorganic ligands to the total number of a plurality of the organic ligands and the plurality of inorganic ligands in the first region is in a range of 8.2% or more and 82% or less.

15. The display device according to claim 1,
wherein the first region includes the organic ligand, and
the ratio of the plurality of inorganic ligands to the total number of a plurality of the organic ligands and the plurality of inorganic ligands in the first region is in a range of 41% or more and 82% or less.

16. The display device according to claim 1,
wherein the first region includes only the inorganic ligand, of the organic ligand and the inorganic ligand.

17. The display device according to claim 1,
wherein a region other than the second region in the light-emitting layer of the at least one subpixel is the first region.

18. The display device according to claim 1,
wherein the light-emitting layer of the at least one subpixel includes the quantum dot, the organic ligand, and the inorganic ligand,
the light-emitting layer of the at least one subpixel further includes a third region, a number of the plurality of inorganic ligands included per unit volume being less than the number of the plurality of inorganic ligands included per unit volume in the first region and greater than the number of the plurality of inorganic ligands included per unit volume in the second region, and
the third region is provided between the first region and the second region.

19. (canceled)

20. A manufacturing method for a display device including a plurality of subpixels, each of the plurality of subpixels including a first electrode, a second electrode, and a function layer provided between the first electrode and second electrode and including at least a light-emitting layer, the manufacturing method for the display device comprising:
forming the first electrode;
forming the function layer; and
forming the second electrode,
wherein the forming the function layer includes forming the light-emitting layer, and
in the forming the light-emitting layer,
as the light-emitting layer of at least one subpixel of the plurality of subpixels, the light-emitting layer is formed that includes
a first region including a quantum dot and including, of an organic ligand and an inorganic ligand, at least the inorganic ligand, and
a second region including the quantum dot and including, of the organic ligand and the inorganic ligand, at least the organic ligand, a number of a plurality of the inorganic ligands contained per unit volume being less than a number of the plurality of inorganic ligands contained per unit volume in the first region, and
the first region includes a central portion of the light-emitting layer of the at least one subpixel, and
the second region includes at least one end portion among end portions, of the light-emitting layer of the at least one subpixel, adjacent to other subpixels adjacent respectively to the at least one subpixel.

21. The manufacturing method for the display device according to claim 20,
wherein, in the forming the light-emitting layer, the plurality of inorganic ligands are supplied to a region, of the light-emitting layer of the at least one subpixel, forming the first region and including a central portion of the light-emitting layer of the at least one subpixel.

22-23. (canceled)

24. The manufacturing method for the display device according to claim 21,
wherein, in the forming the light-emitting layer, the plurality of inorganic ligands are supplied simultaneously to regions, of the light-emitting layers of at least two of the subpixels of the plurality of subpixels, forming the first regions and including the central portions of the light-emitting layers of the at least two subpixels.

25. The manufacturing method for the display device according to claim 20,
wherein the plurality of subpixels in the display device include a first subpixel including a first light-emitting layer as the light-emitting layer, a second subpixel including a second light-emitting layer as the light-emitting layer, and a third subpixel including a third light-emitting layer as the light-emitting layer,
the first light-emitting layer includes a first quantum dot as the quantum dot, a first organic ligand as the organic ligand, and a first inorganic ligand as the inorganic ligand,
the second light-emitting layer includes a second quantum dot as the quantum dot, a second organic ligand as the organic ligand, and a second inorganic ligand as the inorganic ligand,
the third light-emitting layer includes a third quantum dot as the quantum dot, a third organic ligand as the organic ligand, and a third inorganic ligand as the inorganic ligand,
the forming the light-emitting layer includes
forming the first light-emitting layer on the first subpixel,
forming the second light-emitting layer on the second subpixel, and
forming the third light-emitting layer on the third subpixel,
the forming the first light-emitting layer includes
forming a first resist layer by applying a first resist to entirely cover the plurality of subpixels,
patterning the first resist layer by exposing and developing the first resist layer to remove the first resist layer corresponding to a planned formation region of the first light-emitting layer,
forming a first quantum dot containing layer, subsequent to the patterning the first resist layer, to entirely cover the plurality of subpixels, the first quantum dot containing layer including the first quantum dot and at least the first organic ligand of the first organic ligand and the first inorganic ligand,
patterning the first quantum dot containing layer by lifting off the first quantum dot containing layer on the first resist layer, in such a manner as to remove the first quantum dot containing layer corresponding to a region other than the planned formation region of the first light-emitting layer,
forming a second resist layer, subsequent to the patterning the first quantum dot containing layer, by applying a second resist to entirely cover the plurality of subpixels,
first patterning the second resist layer by exposing and developing the second resist to form, in the second resist layer, a first opening that exposes a region forming the first region of the first light-emitting layer and including a central portion of the first quantum dot containing layer, and
supplying the first inorganic ligand to a region, of the first quantum dot containing layer, exposed from the first opening,
the forming the second light-emitting layer includes
re-applying a second resist to an inside of the first opening, subsequent to the supplying the first inorganic ligand, in such a manner as to refill the first opening with the second resist,
second patterning the second resist layer, subsequent to the re-applying the second resist, by exposing and developing the second resist layer to remove the second resist layer corresponding to a planned formation region of the second light-emitting layer in the subpixel,
forming a second quantum dot containing layer, subsequent to the second patterning the second resist layer, in such a manner as to entirely cover the plurality of subpixels, the second quantum dot containing layer including the second quantum dot and at least the second organic ligand of the second organic ligand and the second inorganic ligand, and
patterning the second quantum dot containing layer by lifting off the second quantum dot containing layer on the second resist layer, in such a manner as to remove the second quantum dot containing layer corresponding to a region other than the planned formation region of the second light-emitting layer.

26-31. (canceled)
